(19) United States
(12) Patent Application Publication
(10) Pub. No.: US 2011/0295530 A1
(43) Pub. Date: Dec. 1, 2011

(54) FAULT DIAGNOSIS DEVICE FOR AMPLITUDE MODULATION DEVICE

(75) Inventors: Takahumi OOWADA, Kariya-shi (JP); Hiroya TSUJI, Yokkaichi-shi (JP); Tatsuru MORIOKA, Okazaki-shi (JP); Hiroshi INAMURA, Nagoya (JP); Makoto OKAMURA, Nisshin-shi (JP)

(73) Assignee: DENSO CORPORATION, Kariya-city (JP)

(21) Appl. No.: 13/117,383

(22) Filed: May 27, 2011

(30) Foreign Application Priority Data
May 28, 2010 (JP) 2010-122825
Oct. 25, 2010 (JP) 2010-238510
May 18, 2011 (JP) 2011-111840

(51) Int. Cl. G01R 31/02; G06F 19/00

(52) U.S. Cl. 702/58; 324/537

(57) ABSTRACT

The fault diagnosis device is for diagnosing presence of a fault in an amplitude modulation device which modulates an amplitude of a carrier wave signal to generate a modulated wave signal, comprising. The fault diagnosis device includes a sampling means to perform sampling of at least one of the carrier wave signal and the modulated wave signal at a period different from a period of the carrier wave signal, and a diagnosis means to perform diagnosis of presence of a fault in the amplitude modulation device based on sampled values outputted from the sampling means.

This application claims priority to Japanese Patent Applications No. 2010-122825 filed on May 28, 2010, No. 2010-238510 filed on Oct. 25, 2010, and No. 2011-111840 filed on May 18, 2011, the entire contents of which are hereby incorporated by reference.

### BACKGROUND OF THE INVENTION

1. Field of the Invention

The present invention relates to a fault diagnosis device for diagnosing presence of a fault in an amplitude modulation device which modulates the amplitude of a carrier wave signal to generate a modulated wave signal.

2. Description of Related Art

A resolver, which is known as an amplitude modulation device used as a rotational angle sensor, has such a structure that a first coil rotating together with a rotor and supplied with an excitation signal generates a rotating magnetic flux, a second coil applied with this generated magnetic flux induces a voltage, and the rotational angle of the first coil (that is, the rotational angle of the rotor) is detected based on the induced voltage. For example, refer to Japanese Patent No. 3136937

In the resolver as described above, if the electrical current path between the first coil rotating together with the rotor and a voltage detecting means is broken, the output of the resolver does not represent the rotational angle of the rotor. Accordingly, it is desirable to provide the resolver with a function of detecting whether the resolver is operating normally.

Such a function is desired for any amplitude modulation device which modulates the amplitude of a carrier wave signal to generate a modulated wave signal, other than the resolver as described above.

### SUMMARY OF THE INVENTION

An embodiment provides a fault diagnosis device for diagnosing presence of a fault in an amplitude modulation device which modulates an amplitude of a carrier wave signal to generate a modulated wave signal, comprising:

a sampling means to perform sampling of at least one of the carrier wave signal and the modulated wave signal at a period different from a period of the carrier wave signal; and

a diagnosis means to perform diagnosis of presence of a fault in the amplitude modulation device based on sampled values outputted from the sampling means.

Another embodiment provides a fault diagnosis device for diagnosing presence of a fault in an amplitude modulation device which modulates an amplitude of a carrier wave signal to generate a modulated wave signal, comprising:

a sampling means to perform sampling of the modulated wave signal; and

a diagnosis means to perform diagnosis of presence of a fault based on sampled values of the modulated wave signal outputted from the sampling means,

wherein the sampling means includes a prevention means to prevent the diagnosis from being performed by the diagnosis means based on only the sampled values sampled at the same phase.

According to the present invention, there is provided a fault diagnosis device capable of accurately diagnosing presence of a fault in an amplitude modulation device which modulates the amplitude of a carrier wave signal to generate a modulated wave signal.

Other advantages and features of the invention will become apparent from the following description including the drawings and

### BRIEF DESCRIPTION OF THE DRAWINGS

In the accompanying drawings

FIG. 1 is a diagram showing the structure of a resolver for use in an M/G (motor/generator) as a vehicle main engine, provided with a fault diagnosis device according to a first embodiment of the invention;

FIG. 2A is a time chart showing sampled values of the resolver output when the resolver operates normally; FIG. 2B is a time chart showing sampled values of the resolver output when the resolver is faulty;

FIG. 3 is a flowchart showing steps of a fault diagnosis process performed by the fault diagnosis device according to the first embodiment of the invention;

FIG. 4 is a flowchart showing steps of a fault diagnosis process performed by a fault diagnosis device according to a second embodiment of the invention;

FIG. 5 is a flowchart showing steps of a fault diagnosis process performed by a fault diagnosis device according to a third embodiment of the invention;

FIG. 6 is time charts for explaining a principle of a fault diagnosis performed by a fault diagnosis device according to a fourth embodiment of the invention;

FIG. 7 is a flowchart showing steps of a fault diagnosis process performed by the fault diagnosis device according to the fourth embodiment of the invention;

FIG. 8 is time charts for explaining principle of a fault diagnosis performed by a fault diagnosis device according to a fifth embodiment of the invention;

FIG. 9 is a flowchart showing steps of a fault diagnosis process performed by a fault diagnosis device according to a sixth embodiment of the invention;

FIG. 10 is a time chart for explaining principle of a fault diagnosis performed by a fault diagnosis device according to a seventh embodiment of the invention;

FIG. 11 is a flowchart showing steps of a fault diagnosis process performed by the fault diagnosis device according to the seventh embodiment of the invention;

FIGS. 12A and 12E are diagrams charts for explaining the principle of a fault diagnosis performed by a fault diagnosis device according to an eighth embodiment of the invention;

FIGS. 13A to 13C are time charts for explaining the principle of a fault diagnosis performed by a fault diagnosis device according to a ninth embodiment of the invention;

FIG. 14 is a flowchart showing steps of a fault diagnosis process performed by the fault diagnosis device according to the ninth embodiment of the invention;

FIGS. 15A to 15C are time charts for explaining principle of a fault diagnosis performed by a fault diagnosis device according to a tenth embodiment of the invention;

FIG. 16 is a flowchart showing steps of a fault diagnosis process performed by the fault diagnosis device according to the tenth embodiment of the invention;

FIGS. 17A and 17B are diagrams showing an example of a fault as an diagnostic object of a fault diagnosis device according to an eleventh embodiment of the invention;

FIG. 18 is a flowchart showing steps of a fault diagnosis process performed by the fault diagnosis device according to the eleventh embodiment of the invention;

FIG. 19 is time charts for explaining operation of the fault diagnosis device according to the eleventh embodiment of the invention;

FIG. 20 is time charts for explaining advantages of the eleventh embodiment;

FIG. 21 is a flowchart showing steps of a fault diagnosis process performed by a fault diagnosis device according to a twelfth embodiment of the invention;

FIGS. 22A and 22B are time charts for explaining advantages of the twelfth embodiment of the invention;

FIG. 23 is a diagram showing the stricture of a resolver for use in an M/G as a vehicle main engine, provided with a fault diagnosis device according to a thirteenth embodiment of the invention;

FIG. 24 is a functional block diagram explaining a fault diagnosis process performed by the fault diagnosis device according to the thirteenth embodiment of the invention;

FIG. 25 is a diagram showing the structure of a resolver for use in an M/G as a vehicle main engine, provided with a fault diagnosis device according to a fourteenth embodiment of the invention;

FIGS. 26A and 26B are time charts showing a fault to be diagnosed by a fault diagnosis device according to a fifteenth embodiment of the invention; and

FIGS. 27A and 27B are diagrams explaining fault diagnosis criteria in the fault diagnosis device according to the fifteenth embodiment of the invention.

### PREFERRED EMBODIMENTS OF TEE INVENTION

### First Embodiment

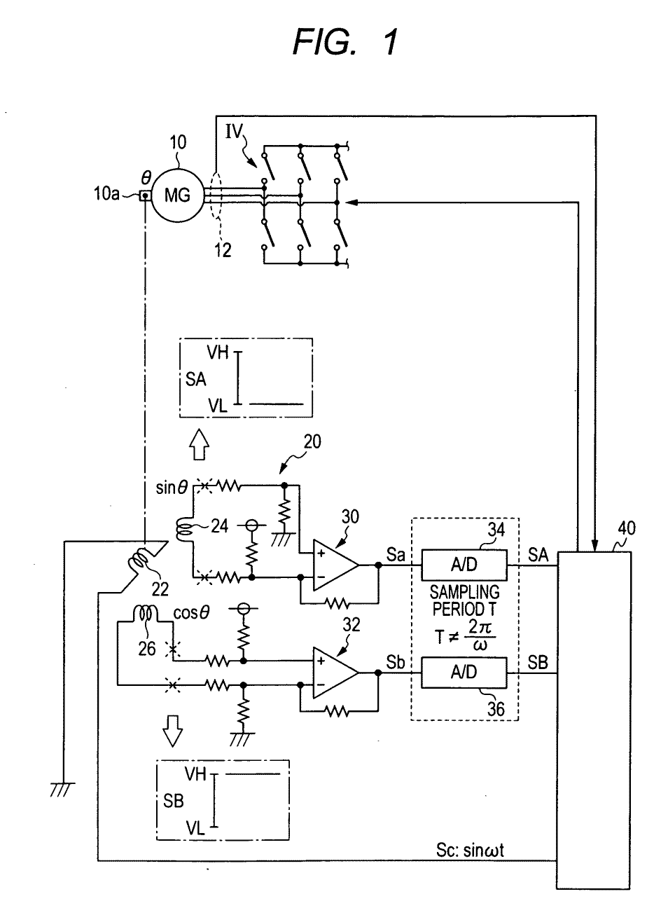

FIG. 1 is a diagram showing the structure of a resolver 2D as an amplitude modulation device for use in an M/G (motor/generator) 10, provided with a fault diagnosis device according to a first embodiment of the invention.

The M/G 10, which is used as a vehicle main engine is coupled to the drive wheels of a vehicle. An inverter IV mediates electrical power transmission between the M/G 10 and a battery (not shown) A rotor 10a of the M/G 10 is mechanically coupled with a primary coil 22 of the resolver 20. The primary coil 22 is excited with a sinusoidal excitation signal Sc. The magnetic flux generated in the primary coil 22 in accordance with the excitation signal Sc interlinks with a pair of secondary coils 24 and 26. The positional relationship between the primary coil 22 and each of the secondary coils 24 and 26 varies periodically in accordance with the electrical angle (rotational angle θ) of the rotor 10a. Accordingly, the number of the lines of the magnetic flux interlinking with the secondary coils 24 and 26 varies periodically. In this embodiment, the geometrical position of the secondary coil 24 with respect to the primary coil 22 is different from that of the secondary coil 26 such that the output voltages (induced voltages) of the secondary coils 24 and 26 differ in phase from each other by π/2 radians. Accordingly, the output voltages of the secondary coils 24 and 26 are modulated versions of the excitation signal Sc. That is, the output voltages of the secondary coils 24 and 26 are modulated wave signals generated by modulating the excitation signal Sc with a modulation wave signal sin θ and a modulation wave signal cos θ, respectively. When the excitation signal Sc is represented by sin ωt, the modulated wave signals outputted from the secondary coils 24 and 26 are represented by sin θ sin ωt and cos θ sin ωt, respectively.

The output voltage of the secondary coil 24 is voltage-converted into an A-phase modulated wave signal Sa by a differential amplifier 30, and the output voltage of the secondary coil 26 is voltage-converted into a B-phase modulated wave signal Sb by a differential amplifier 32. The A-phase modulated wave signal Sa and the B-phase modulated wave signal Sb are converted into digital data by A/D converters 34 and 36, respectively. In the following, these digital data are referred to as sampled signals SA and SB, respectively.

The positive input terminal of an operational amplifier constituting the differential amplifier 30 is pulled down through a resistor, and the negative input terminal of this operational amplifier is pulled up through a resistor. This configuration is for keeping the A-phase modulated wave signal Sa at a constant value, if a wire breakage occurs at places shown by the mark X in FIG. 1. In this embodiment, this constant value is set below the lower limit value VI that the A-phase modulated wave signal Sa can take in the normal state, that is when the resolver 20 operates normally. The input conversion range of the A/D converter 34 is set to coincide with the range from the lower limit value VL and the higher limit value VH of the A-phase modulated wave signal Sa. Accordingly, if the constant value is set lower than the lower limit value VL, the value of the sampled signal SA outputted from the A/D converter 34 coincides with the lower limit value VL.

The positive input terminal of an operational amplifier constituting the differential amplifier 32 is pulled up through a resistor, and the negative input terminal of this operational amplifier is pulled down through a resistor. This configuration is for keeping the B-phase modulated wave signal Sb at a constant value, if a wire breakage occurs at places shown by the mark X in FIG. 1. In this embodiment, this constant value is set below the lower limit value VL that the B-phase modulated wave signal Sb can take in the normal stage. The input conversion range of the A/D converter 36 is set to coincide with the range from the lower limit value VL and the higher limit value VH of the B-phase modulated wave signal Sb. Accordingly, if the constant value is set higher than the higher limit value VH, the value of the sampled signal SB outputted from the A/D converter 36 coincides with the higher limit value VH.

A control device 40 detects the rotational angle θ and the current of the M/G 10 as controlled variables based on the rotational angle signal (the sampled signals SA and SB) outputted from the resolver 20 and the output signal of a current sensor 12, in order to control the M/G 10.

The period T of the sampling cycle of the sampled signals SA and SB is set different from the period of 2π/ω of the excitation signal Sc. Preferably, this period of the sampling cycle T is set smaller than 90% or larger than 110% of the period of 2π/ω of the excitation signal Sc. The reason why the A-phase modulated wave signal and the B-phase modulated wave signal are sampled asynchronously with the excitation signal Sc is to reliably perform a diagnosis of presence of a fault of the resolver 20 based on the sampled signals SA and SB. This is explained in more detail in the following.

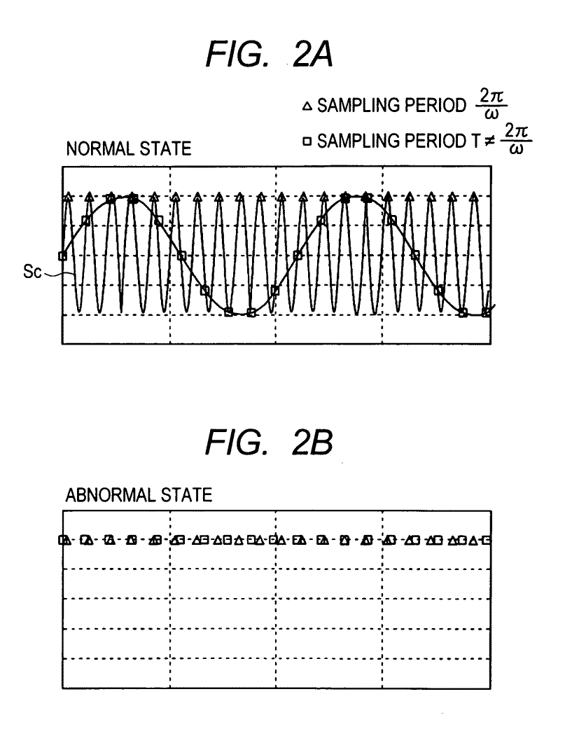

FIG. 2A is a time chart showing variation with time of the output signal of the resolver 20 in the normal state when the rotor 10a is stationary, assuming that the rotational angle θ is fixed at a position at which the B-phase modulated wave signal takes its maximum. In this case, if the sampling is performed synchronously with the excitation signal Sc by setting the period of the sampling cycle to 2π/ω, the sampled signal SB is kept at a constant value shown by the mark Δ which coincides with the higher limit value VH. Accordingly, in this case, it is not possible to determine whether the resolver 20 is normal or faulty, because it is not possible to distinguish between the case where the rotor 10a is stationary and the case where there is a wire breakage between the secondary coil 26 and the differential amplifier 32 (see FIG. 2B). According to this embodiment, since the sampling is performed asynchronously with the excitation signal Sc, the value of sampled signal SA varies with time as shown by the mark □ in FIG. 2A even when the rotor 10a is stationary as long as the resolver 20 functions normally. This makes it possible to distinguish between the normal state and the abnormal state of the resolver 20.

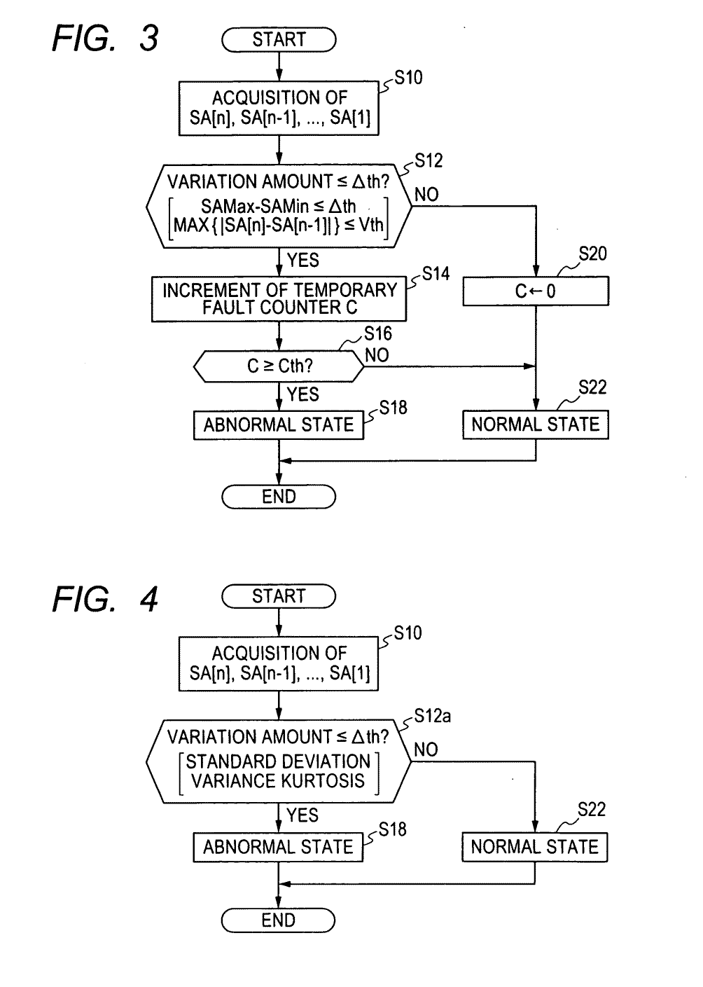

Next, a fault diagnosis process performed in this embodiment is explained with reference to the flowchart of FIG. 3. This process is performed repeatedly at regular time intervals by the control device 40. The process shown in FIG. 3 is mainly directed to a diagnosis of presence of a fault in the secondary coil 24

This process begins at step S10 to acquire values SA [n], SA [n−1], . . . , SA[1] of the sampled signal SA. In subsequent step S12, it is determined whether or not the amount of variation of the acquired values of the sampled signal SA is smaller than or equal to a predetermined value Step S12 is for determining whether the resolver 20 is normal or faulty. If the resolver 20 is normal, the values of the sampled signal A vary synchronously with the variation of the excitation signal Sc. If there is a fault such as a wire breakage in the secondary coil 24, the sampled signal SA is fixed to the lower limit value VL. Accordingly, it is possible to determine that there is a fault in the resolver 20 if the variation of the values of the sampled signal SA is small.

In this embodiment it is determined that the amount variation of the values of the sampled signal SA is smaller than or equal to the predetermined value, if the following conditions 1 and 2 are satisfied.

1. The difference between the maximum value SAmax and the minimum value SAmin of the sampled signal SA is smaller than or equal to a threshold Δth. The maximum value SAmax may be determined from the values of the sampled signal SA exclusive of a few largest ones of these values in order to eliminate the effect of noise. Likewise, the minimum value SAmin may be determined from the values of the sampled signal SA exclusive of a few smallest ones of these values in order to eliminate the effect of noise.

2. The maximum value of the variation rates (SA[n]-SA[n−1], SA[n−1]-SA [n−2], . . . SA[2]-SA [1]) of the sampled signal SA is smaller than or equal to a threshold Vth.

If it is determined that the amount of variation of the acquired values of the sampled signal SA is smaller than or equal to the predetermined value, the process proceeds to step S14 to increment a temporary fault counter C which is for counting the number of times that the amount of the variation is determined to be smaller than or equal to the predetermined value. In subsequent step S16, it is determined whether or not the count value of the temporary fault counter C is larger than or equal to a threshold Cth. If the determination result in step S16 is affirmative, a determination that there is a fault is made in step S18. If the determination result in step S12 is negative, the temporary fault counter C is reset in step S20. When step S20 is completed or a negative determination is made in step S16, a determination that there is no fault, that is, the resolver 20 is normal is made in step S22.

When step S18 or S22 is completed, this process is terminated.

The sampled signal SB is processed in the same way as above to determine whether there is a fault or not. It is preferable to determine that the secondary coil 24 is broken if it is determined that there is a fault only by the diagnosis based on the sampled signal SA, and to determine that the secondary coil 26 is broken if it is determined there is a fault only by the diagnosis based on the sampled signal SB. If it is determined there is a fault by the diagnosis based on both the sampled signal SA and the sampled signal SE, it may be determined that the primary coil 22 is broken.

The first embodiment described above provides the following advantages.

(1) The A-phase modulated wave signal Sa and the B-phase modulated wave signal Sb are sampled asynchronously with the period of the excitation signal Sc. This makes it possible to prevent the sampled signals SA and SB from being fixed at a constant value, and allows them to vary in accordance with the variation of the excitation signal Sc.

Accordingly, it is possible to determine whether there is a fault base on the amount of variation of the values of the sampled signal SA or SE,

(2) The output value of the differential amplifiers 30 or 32 is kept at a constant value if the connection to the secondary coil 24 or 26 is broken. This improves reliability of the fault diagnosis.

(3) The constant value is set different from the amplitude center value of the A-phase modulated wave signal Sa or the B-phase modulated wave signal Sb. This makes it possible to distinguish between the case where the modulated wave signal takes the amplitude center value and the case where there is a wire breakage.

(4) It is determined that there is a fault if the amount of variation in value of the sampled signal is small. Since the sampled signal varies in value synchronously with the excitation signal Sc in the normal state, it is possible to determine that there is a fault if the amount of variation in value of the sampled signal is small.

### Second Embodiment

Next, a second embodiment of the invention is described with particular emphasis on the difference with the first embodiment.

FIG. 4 is a flowchart showing steps of a fault diagnosis process performed in the second embodiment. This process is performed repeatedly at regular time intervals by the control device 40. In FIG. 4, the same step numbers as those shown in FIG. 3 represent the same steps.

In this process, to determine whether the amount of variation of the sampled signal is smaller than or equal to a predetermined value, the sampled signal is statistically processed in step S12a. More specifically, in view of that the amount of variation of the sampled signal becomes substantially 0 when there is a wire breakage, the span of the values of the sampled signal is quantified using the standard deviation or variance. Further, the amount of variation may be quantified by graphing out frequencies with which the respective values of the sampled signals appear, and detecting the difference between the largest frequency and the next largest frequency as a kurtosis.

### Third Embodiment

Next, a third embodiment of the invention is described with particular emphasis on the difference with the first embodiment.

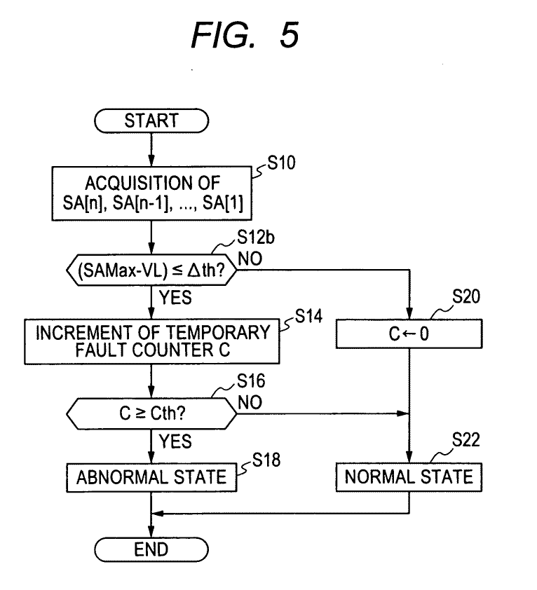

FIG. 5 is a flowchart showing steps of a fault diagnosis process performed in the third embodiment. This process is performed repeatedly at regular time intervals by the control device 40. In FIG. 5, the same step numbers as those shown in FIG. 3 represent the same steps.

In this process, it is determined in step S12b whether or not the variation of the sampled signal SA from the lower limit value VL is smaller than or equal to a predetermined value. More specifically, it is determined in step S12b whether or not the largest value SAmax of the sampled signal SA minus the lower limit value VL is smaller than or equal to a threshold Δth.

According to the third embodiment, other than the above advantages (1) to (3) provided by the first embodiment, the following advantage can be provided.

(5) The diagnosis of presence of a fault is performed based on the deviation between the sampled signal SA or SB and the constant value VL or VH. Since the sampled signal varies in value synchronously with the excitation signal Sc in the normal state, it is possible to determine whether or not there is a fault based on the deviation between the sampled signal SA or SB and the constant value VL or VH.

### Fourth Embodiment

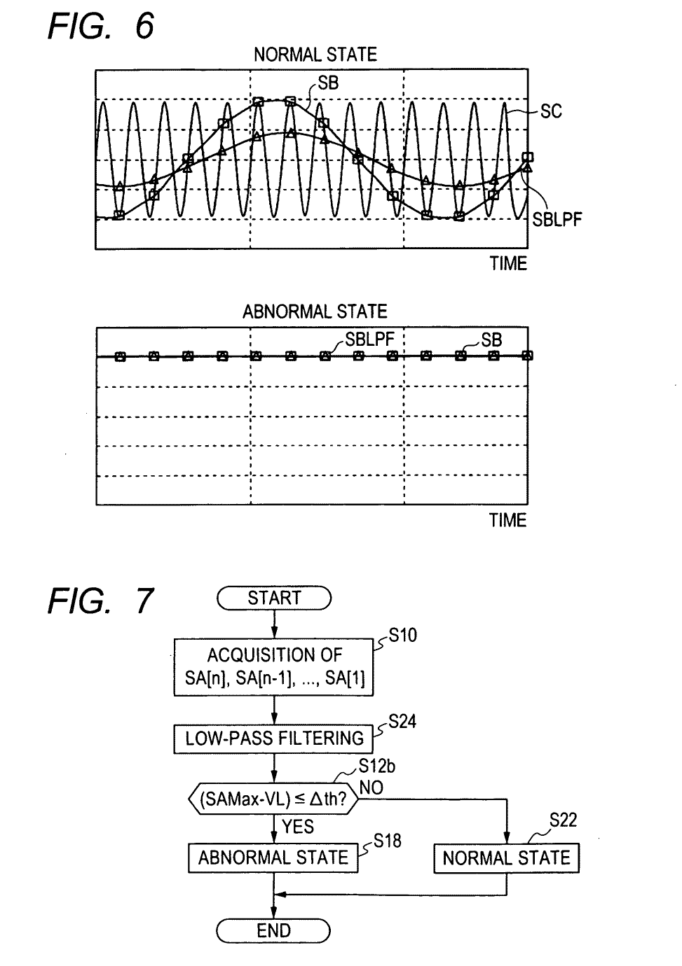

Next, a fourth embodiment of the invention is described with particular emphasis on the difference with the third embodiment. In the fourth embodiment, the diagnosis of presence of a fault is performed based on the filtered sampled signals SA or SB, instead of the deviation between the sampled signal SA or SB with the constant value (VL or VH). FIG. 6 shows a signal SBLPF which is a low-pass filtered version of the sampled signal SB. As shown in FIG. 6, the signal SBLPF has a sinusoidal waveform and a smaller amplitude than the sampled signal SB when the resolver is normal. Accordingly, in this embodiment, the deviation from the constant value (higher limit value VH) is enhanced.

FIG. 7 is a flowchart showing steps of a fault diagnosis process performed in the fourth embodiment. This process is performed repeatedly at regular time intervals by the control device 40. In FIG. 7, the same step numbers as those shown in FIG. 5 represent the same steps.

In this process, after step S10, the sampled signal SA is filtered by a low-pass filter in step S24. In this embodiment, the low pass filter is a first-order lag filter. In step S12, it is determined whether or not the deviation of the output of the low-pass filter from the lower limit value VL is smaller than or equal to a predetermined value.

According to the fourth embodiment, other than the above advantages provided by the third embodiment, the following advantage can be provided.

(6) The deviation from the constant value (VL or VH) of the sampled signal SA or SB having been low-pass filtered is quantified. This makes it possible to further improve the accuracy of the fault diagnosis, because the difference of the output of the low-pass filter when the resolver 20 is normal and that when the resolver 20 is faulty is large.

### Fifth Embodiment

Next, a fifth embodiment of the invention is described with particular emphasis on the difference with the third embodiment.

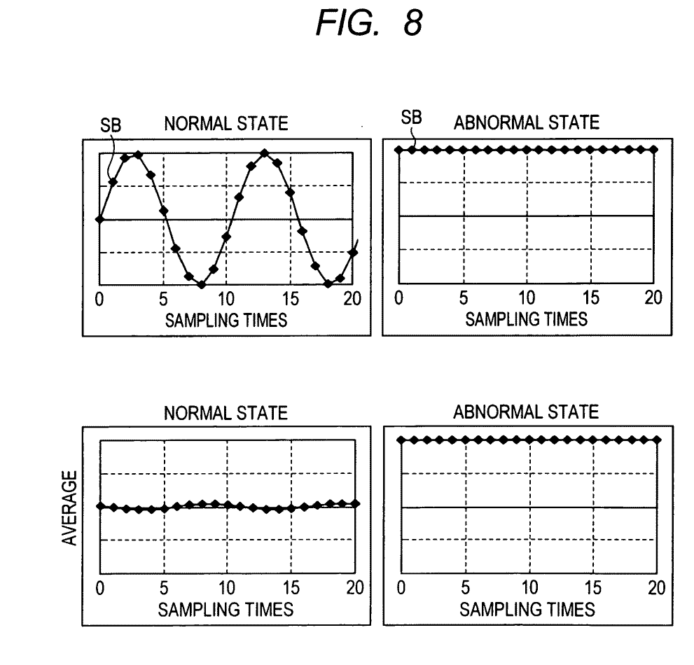

In the fifth embodiment, an average value of each of the sampled signals SA and SE is calculated by a filtering process. Since each of the sampled signals SA and SE has a sinusoidal waveform in the normal state as shown in FIG. 8, the average value is equal to the middle value between the higher limit value VH and the lower limit value VL. On the other hand, the average value is equal to the higher limit value VH or the lower limit value VL in the normal state.

It may be determined that there is a fault if the average value is larger than a first threshold, or smaller than a second threshold. In this embodiment, the first threshold is set to a value (preferably, to the middle value) between the center value of the sampled signal SA or SB in the normal state and the larger one of the constant values (that is, the higher limit value VH) in the abnormal state. Likewise, the second threshold is set to a value (preferably, to the middle value) between the center value of the sampled signal SA or SE in the normal state and the smaller one of the constant values (that is, the lower limit value VL) in the abnormal state.

### Sixth Embodiment

Next, a sixth embodiment of the invention is described with particular emphasis on the difference with the third embodiment.

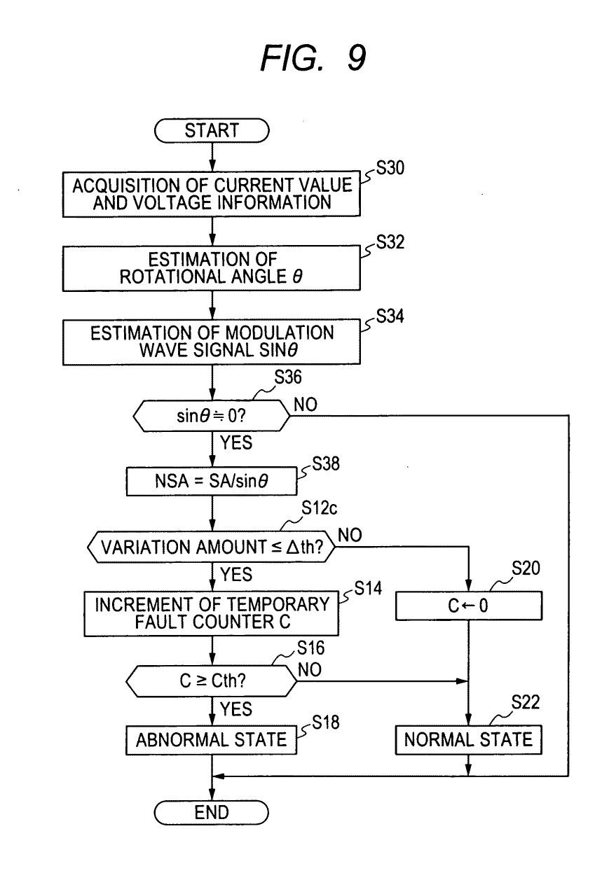

FIG. 9 is a flowchart showing steps of a fault diagnosis process performed in the sixth embodiment. This process is performed repeatedly at regular time intervals by the control device 40. In FIG. 9, the same step numbers as those shown in FIG. 3 represent the same steps.

In this process, the current value detected by the current sensor 12 and voltage information showing the voltage applied to the M/G 10 by the inverter IV are acquired in step S30. In subsequent step S32, the rotational angle θ of the M/G 10 is estimated based on the acquired current value and the voltage information. The rotational angle may be estimated based on the voltage induced in the M/G 10 in its high rotational speed range. For example, when the M/G 10 is an IPSM, this estimation may be made using the method described in “Extended EMF Observer for Sensorless Control of Salient-Pale Brushless DC Motor, The Institute of Electrical Engineers of Japan, No. 1026”. Further, the rotational angle of the M/G 10 may be estimated based on the current response when a harmonic signal having a frequency higher than the electrical angular velocity is applied in its low rotational speed range, as disclosed in Japanese Patent Application Laid-open No. 2009-148017.

In subsequent step S36, it is determined whether or not the modulation wave signal sin θ is nearly 0. If the determination result in step S36 is negative, the process proceeds to step S38 to calculate a normalized signal NSA by dividing the sampled signal SA by the modulation wave signal. If the determination result in step S36 is affirmative, the process is terminated. Step S36 is for preventing the normalized signal NSA from becoming excessively large when the modulation wave signal sine is newly 0. In subsequent step S12c, it is determined whether or not the amount of variation of the normalized signal NSA is smaller than or equal to a predetermined value.

According to the sixth embodiment, other than the advantages provided by the first embodiment, the following advantages can be provided.

(7) The diagnosis of presence of a fault is performed based on the amount of variation of the normalized signal NSA. This makes it possible to perform the diagnosis of presence of a fault based on whether the variation of the excitation signal Sc affects the sampled signal, irrespective of the magnitude of the modulation wave signal.

(8) When the modulation wave signal is small, the fault diagnosis is inhibited from being performed. This improves the accuracy of the fault diagnosis.

### Seventh Embodiment

Next, a seventh embodiment of the invention is described with particular emphasis on the difference with the first embodiment.

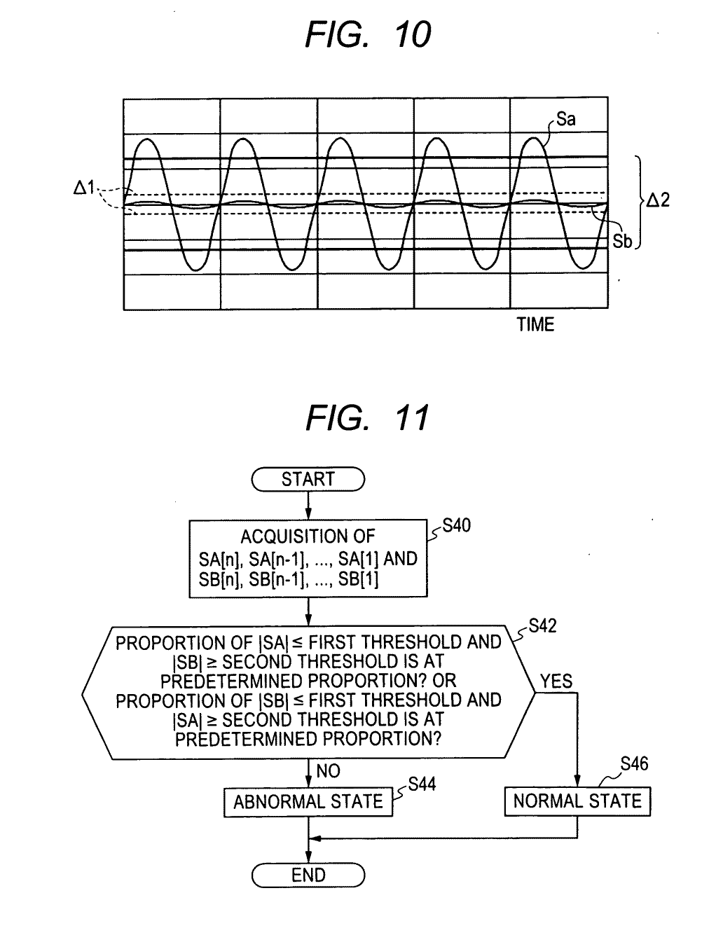

In the seventh embodiment, the diagnosis of presence of a fault is performed based on the phase difference between the A-phase modulated wave signal SA and the B-phase modulated wave signal Sb. As shown in FIG. 10, there occurs a phenomenon that the variation with time of one of the modulated wave signals (the B-phase modulated wave signal Sb in FIG. 10) is within a variation range Δ1, while that of the other (the A-phase modulated wave signal Sa in FIG. 10) exceeds a variation range Δ2. Accordingly, it can be determined that there is a fault if such a phenomenon does not occur.

FIG. 11 is a flowchart showing steps of a fault diagnosis process performed in the seventh embodiment. This process is performed repeatedly at regular time intervals by the control device 40.

In this process, the values SA [n], SA [n−1], . . . , SA[1] of the sampled signal SA, and the values SB [n], SE [n−1], . . . , SB[1] of the sampled signal SB are acquired concurrently. In subsequent step S42, it is determined whether or not, while one of the sampled signals SA and SB is smaller than or equal to a first threshold value in its absolute value, the proportion of the number of the absolute values of the other signal larger than a second threshold value to the whole number of the acquired values of the other signal is at a predetermined proportion. If the determination result in step S42 is negative, a determination that there is a fault is made in step S44. If the determination result in step S42 is affirmative, a determination that there is no fault is made in step S46. Preferably, this predetermined proportion is not set to 0% or 100% in order to prevent the case where it is determined that there is no fault when the sampled signal SA or SB is fixed by a wire breakage. When step S44 or S46 is completed, this process is terminated.

According to the seventh embodiment, other than the above advantages (1) to (3) provided by the first embodiment, the following advantage can be provided.

(9) A determination that there is a fault is made if the difference between the sampled signal SA and the sampled signal SE does not reach a predetermined value. This makes it possible to perform the fault diagnosis using the phase difference between the A-phase and B-phase modulated wave signals.

### Eighth Embodiment

Next, an eighth embodiment of the invention is described with particular emphasis on the difference with the first embodiment

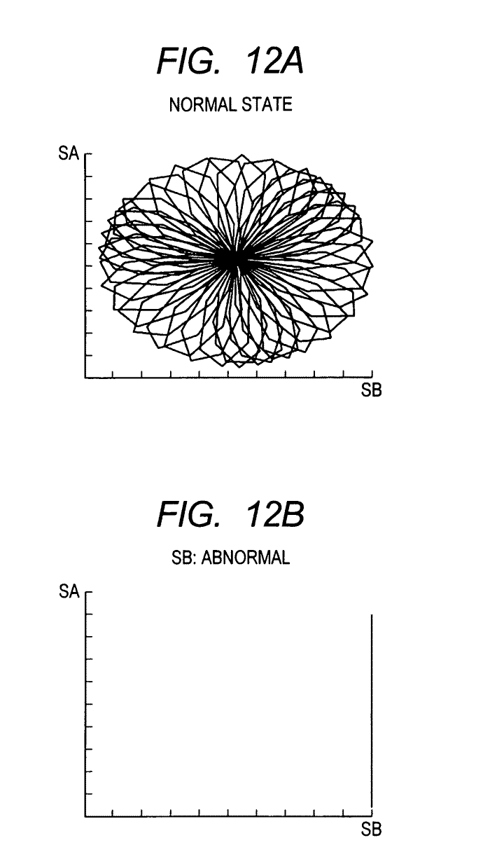

In the eighth embodiment, the diagnosis of presence of a fault is performed based on a distribution of the sampled signals SA and SB on the two-dimensional coordinate system having coordinates (sampled signal SA, sampled signal SB). When there is no fault, since both the sampled signals SA and SB vary between the higher limit value VH and the lower limit value VL, the distribution is as shown in FIG. 12A. On the other hand, if there is a breakage in the secondary coil 28, for example, since the sampled signal SB is kept at the constant value (higher limit value VH), the distribution forms a straight line. Likewise, if there is a breakage in the secondary coil 24, the distribution of the sampled signals SA and SE forms a straight line. If there is a breakage in the primary coil 22, the sampled signals SA and SB are at fixed points, respectively.

Accordingly, if the distance between the distribution of the sampled signals SA and SB and the straight line (SB=VH or SA=VL) is small, or the distance between the distribution of the sampled signals SA and SB and the point (SA, SB)=(VL, VH) is small, it is possible to determine that there is a fault.

### Ninth Embodiment

Next, an ninth embodiment of the invention is described with particular emphasis on the difference with the first embodiment.

In the ninth embodiment, the diagnosis of presence of a fault is performed based on a sum signal AD of the sampled signals SA and SB sampled at the same time. As described in the foregoing, when the excitation signal Sc is sin ωt and the modulation signals are sine and cos θ, the sum of the A-phase modulated wave signal Sa and the B-phase modulated wave signal is (sin θ+cos θ) sin ωt=√2 sin(θ+n/4)sin ωt (if voltage conversions by the differential amplifiers 30 and 32 are disregarded). If there is a breakage in the secondary coil 26, for example, the sum of the A-phase modulated wave signal Sa and the B-phase modulated wave signal is sin θ sin ωt+VH (if voltage conversions by the differential amplifiers 30 and 32 are disregarded), the value of which is larger than when there is no fault

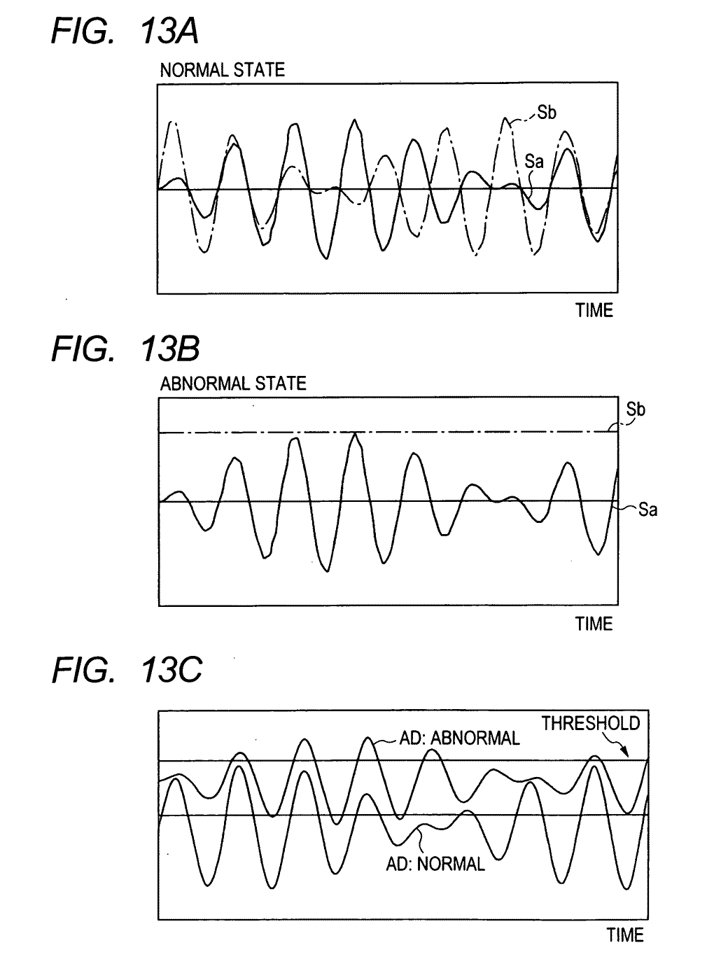

FIG. 13A shows variations with time of the A-phase modulated wave signal Sa and the B-phase modulated wave signal Sb in the normal state. FIG. 13B shows variations with time of the A-phase modulated wave signal Sa and the B-phase modulated wave signal Sb in the abnormal state. FIG. 130 shows variations with time of the sum signal AD of the A-phase modulated wave signal Sa and the B-phase modulated wave signal Sb in each of the normal state and the abnormal state.

As shown in these figures, the sum signal AD in the abnormal state may take a value which it cannot take in the normal state. Accordingly, by using a threshold value which the sum signal AD cannot take in the normal state, it is possible to perform the diagnosis of presence of a fault.

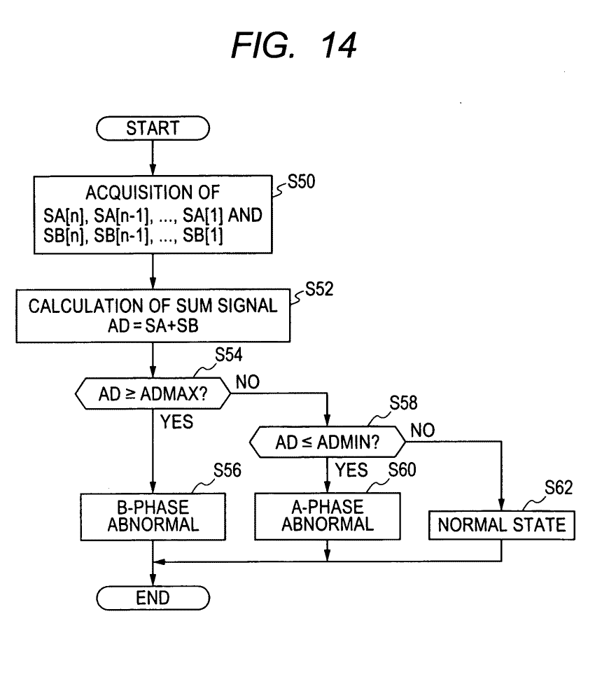

FIG. 14 is a flowchart showing steps of a fault diagnosis process performed in the ninth embodiment. This process is performed repeatedly at regular time intervals by the control device 40.

In this process, the values SA [n], SA [n−1], . . . , SA[1] of the sampled signal SA, and the values SB [n], SB [n−1], . . . , SB [1] of the sampled signal SB are acquired concurrently. In subsequent step S52, sums of pairs of the values of the sampled signals SA and SA sampled at the same time SA [n]+SB[n], SA[n−1]+SB [n−1], . . . , SA[1]+SB[1] are calculated as the sum signals AD. In subsequent step S54, it is determined whether or not at least one of the sum signals AD is larger than or equal to a threshold ADMAX. If the determination result in step S54 is affirmative, a determination that there is a breakage in the secondary coil 26 (B-phase fault) is made in step S56.

If the determination result in step S54 is negative, the process proceeds to step S58 to determine whether or not at least one of the sum signals AD is smaller than or equal to a threshold ADMIN. Step S58 is for determining whether or not there is a breakage in the secondary coil 244. If there is a breakage in the secondary coil 24, the sum of the A-phase modulated wave signal Sa and the B-phase modulated wave signal is cos θ sin ωt+VL (if voltage conversions by the differential amplifiers 30 and 32 are disregarded), the value of which is smaller than that when there info fault. If the determination result in step S58 is affirmative, a determination that there is a breakage in the secondary coil 24 (A-phase fault) is made in step S60.

If the determination result in step S58 is negative, a determination that there is no fault is made in step S62. When step S56, S60 or S62 is completed, this process is terminated.

According to the ninth embodiment, other than the above advantages (1) to (3) provided by the first embodiment, the following advantage can be provided.

(10) The diagnosis of presence of a fault can be performed properly by watching the sum signals AD.

### Tenth Embodiment

Next, a tenth embodiment of the invention is described with particular emphasis on the difference with the first embodiment.

In the tenth embodiment, the diagnosis of presence of a fault is performed based on the sum of the squares of the sampled signals SA and SA sampled at the same time (referred to as the square sum signal MU in the following). As described in the foregoing, when the excitation signal Sc is sin ωt and the modulation signals are sine and cos θ, the sum of the square of the A-phase modulated wave signal Sa and the square of the B-phase modulated wave signal is (sin ωt)2 in the normal state (if voltage conversions by the differential amplifiers 30 and 32 are disregarded). If the secondary coil 26 is broken, for example, the sum of the square of the A-phase modulated wave signal Sa and the square of the B-phase modulated wave signal is (sin θ sin ωt)̂2+VĤ2 (if voltage conversions by the differential amplifiers 30 and 32 are disregarded), the value of which is larger than when there is no fault.

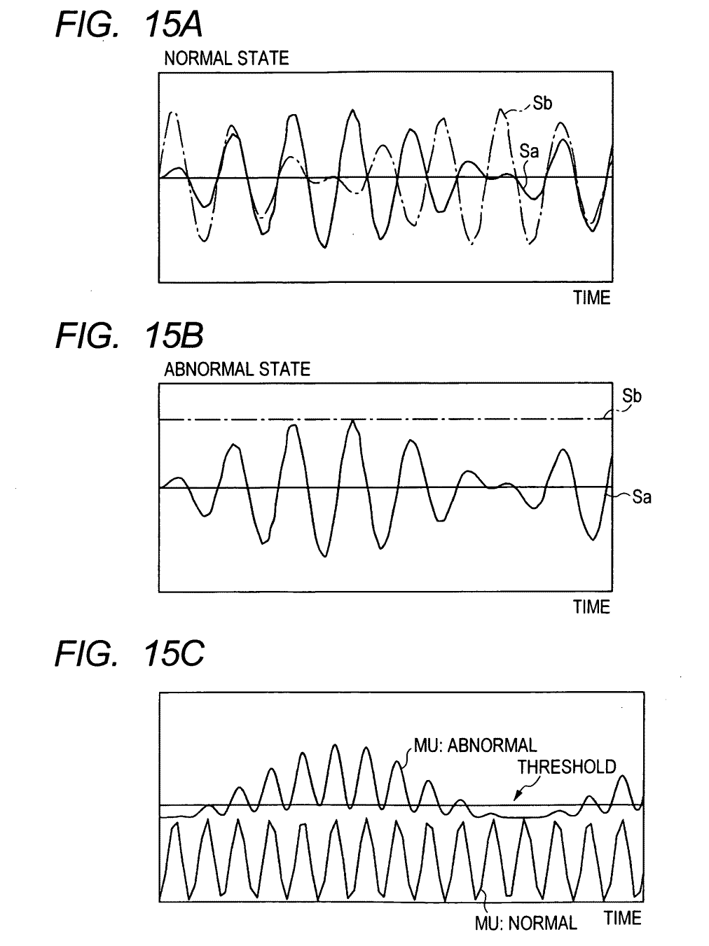

FIG. 15A shows variations with time of the A-phase modulated wave signal Sa and the B-phase modulated wave signal Sb in the normal state. FIG. 15B shows variations with time of the A-phase modulated wave signal Sa and the B-phase modulated wave signal Sb in the abnormal state. FIG. 15C shows variations with time of the square sum signal MU in each of the normal state and abnormal state.

As shown in FIG. 15C, the square sum signal MU in the abnormal state may take a value which it cannot take in the normal state. Accordingly, it is possible to perform the diagnosis of presence of a fault by using a threshold value which the square sum signal MU cannot take in the normal state.

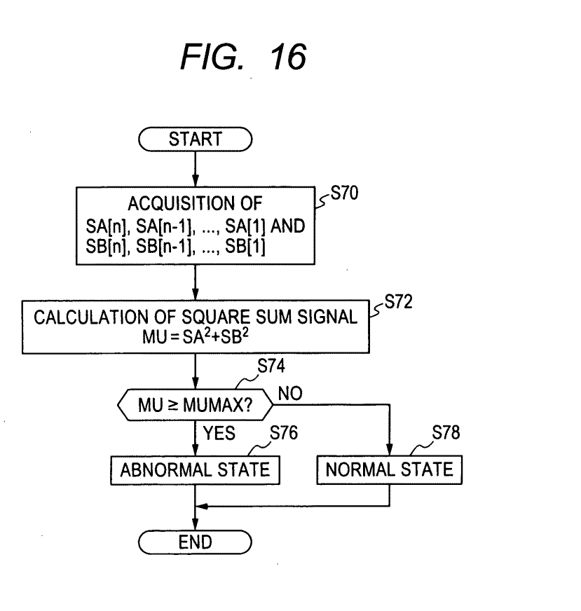

FIG. 16 is a flowchart showing steps of a fault diagnosis process performed in the tenth embodiment. This process is performed repeatedly at regular time intervals by the control device 40.

In this process, the values SA [n], SA [n−1], . . . , SA[1] of the sampled signal SA, and the values SB [n], SB [n−1], . . . , SB[1] of the sampled signal SB are acquired concurrently. In subsequent step S72, the sums of the squares of the sampled signals SA and SB sampled at the same time are calculated successively as the square sum signals MU. In subsequent step S74, it is determined whether or not at least one of the sum signals MU is larger than or equal to a threshold MUMAX. If the determination result in step S74 is affirmative, a determination that there is a breakage in the secondary coil 24 or 25 is made in step S76. If the determination result in step S74 is negative, a determination that there is no fault is made in step S78.

When step S76 or S78 is completed, this process is terminated.

According to the tenth embodiment, other than the above advantages (1) to (3) provided by the first embodiment, the following advantage can be provided.

(11) The diagnosis of presence of a fault can be performed properly by watching the square sum signals MUs.

### Eleventh Embodiment

Next, an eleventh embodiment of the invention is described with particular emphasis on the difference with the tenth embodiment.

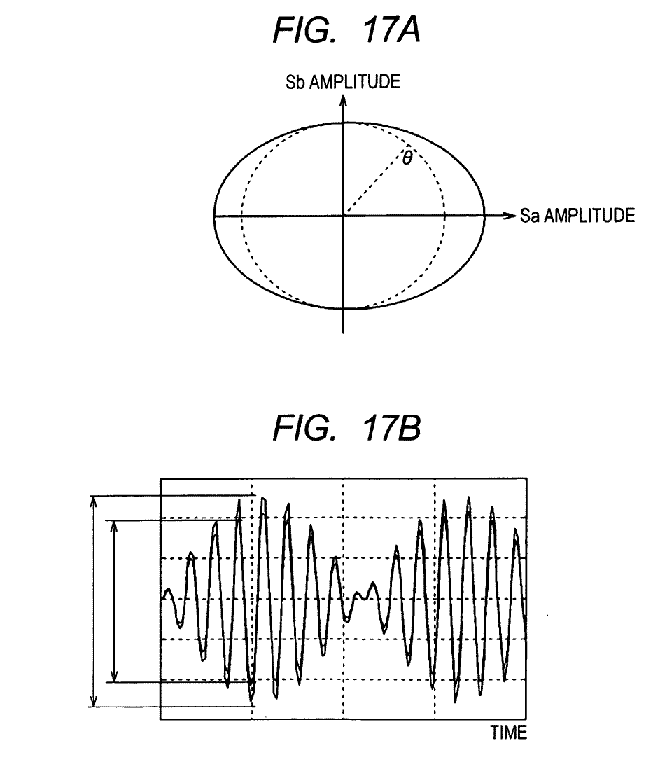

This embodiment is configured to detect a gain fault causing the amplitude of the A-phase modulated wave signal Sa or B-phase modulated wave signal Sb to change abnormally as shown in FIG. 17A. It is difficult to detect a gain fault based on the values of the A-phase modulated wave signal Sa or B-phase modulated wave signal Sb, because their values in the normal state may be the same as those in the abnormal state. Especially, when the maximum value and minimum value of the sampled signals SA or SA coincide with the higher limit value V and the lower limit value VL of the input conversion range of the A/D converter 34 or 36, it is not possible to detect a fault in which the amplitude of the A-phase modulated wave signal Sa or B-phase modulated wave signal Sb increases abnormally by detecting their amplitudes.

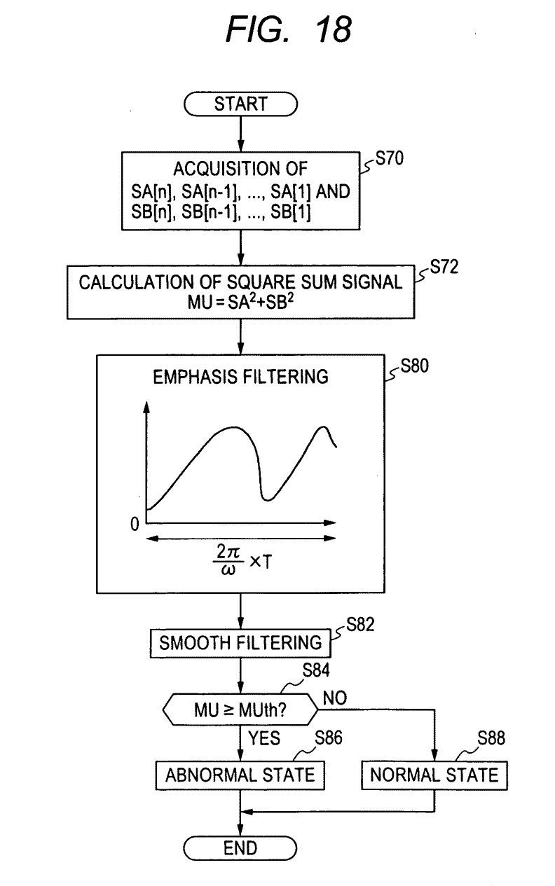

Accordingly, in this embodiment, the process shown in FIG. 18 is performed to detect presence of such a fault. This process is performed repeatedly at regular time intervals by the control device 40. In FIG. 18, the same step numbers as those shown in FIG. 16 represent the same steps

In this process, the square sum signal MU calculated in step S80 is subjected to a filtering process by an emphasis filter. The emphasis filter multiplies the square sum signal MU inputted thereto by a multiplier which varies in the period equal to the product of the period of 2π/ω of the excitation signal Sc and the sampling period T. The emphasis filter is configured to emphasize the difference between the value of the square sum signal MU in the normal state and that in the abnormal state. In subsequent step S82, the square sum signal MU having been subjected to the filtering process is subjected to a smoothing process by a smoothing filter. In subsequent step S84, it is determined whether or not the output signal (the square sum signal MU having been emphasized and smoothed) is larger than or equal to a threshold MUth. If the determination result in step S84 is affirmative, a determination that there is a fault is made in step S86. If the determination result in step S84 is negative, a determination that there is no fault is made in step S88.

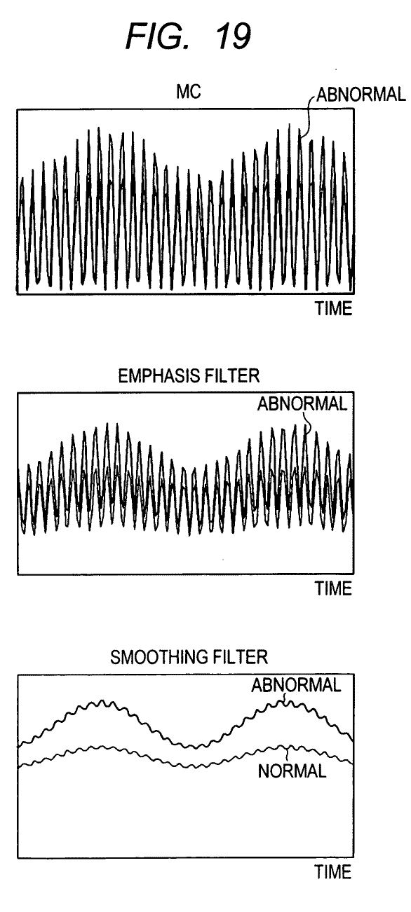

FIG. 19 shows an example of the square sum signal MU, the square sum signal MU having been emphasized or amplified, and the square sum signal MU having been emphasized and smoothed. As shown in FIG. 19, by subjecting the square sum signal MU to the emphasis process, the difference between the value of the square sum signal MU in the normal state and that in the abnormal state can be emphasized, and by further subjecting it to the smoothing process, the value of the square sum signal MU in the normal state and that in the abnormal state can be prevented from overlapping each other.

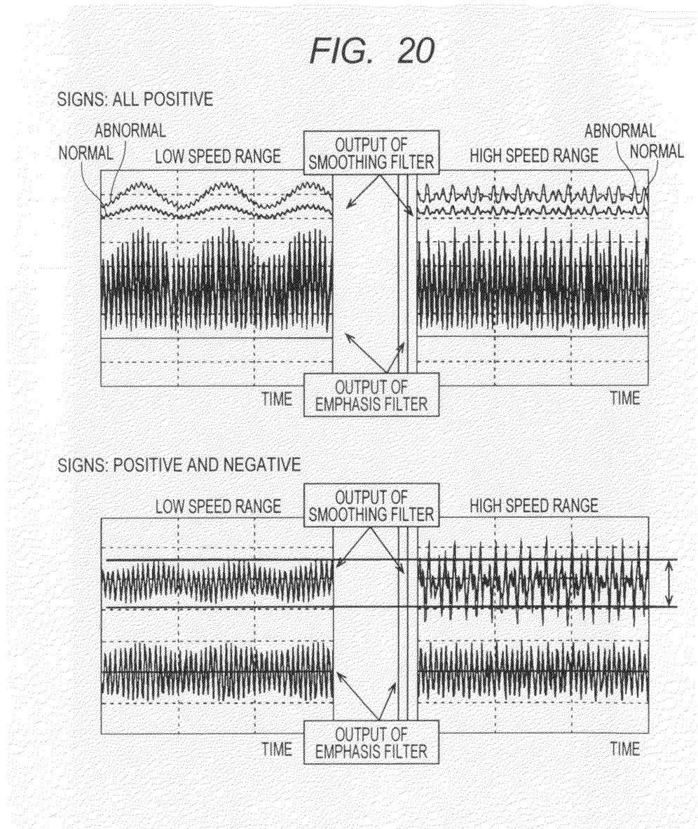

In this embodiment, the values of the multiplier used in the emphasis filter have the same sign to emphasis the difference between the normal state and the abnormal state. FIG. 20 shows comparison between the case where all the values of the multipliers used in the emphasis filter have the same sign, and the case where the values of the multipliers have positive and negative signs. As shown in FIG. 20 when the values of the multipliers have positive and negative signs, the difference between the normal state and the abnormal state cannot be emphasized.

According to the eleventh embodiment, other than the above advantages provided by the tenth embodiment, the following advantage can be provided.

(12) The square sum signal MU is subjected to the emphasis process and the smoothing process. Accordingly, the difference between the normal state and the abnormal state can be emphasized.

### Twelfth Embodiment

Next, a twelfth embodiment of the invention is described with particular emphasis on the difference with the tenth embodiment.

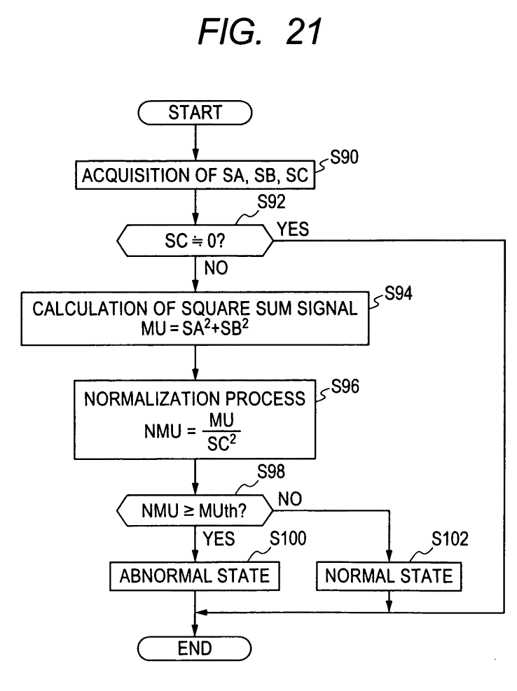

FIG. 21 is a flowchart showing steps of a fault diagnosis process performed in the twelfth embodiment. This process is performed repeatedly at regular time intervals by the control device 40.

In this process, in addition to the sampled signals SA and SB sampled at the same time, a digital signal SC which is A/D-converted from the excitation signal Sc is acquired in step S90. In subsequent step S92, it is determined whether or not the digital signal SC is substantially 0. If the determination result in step S92 is negative, the process proceeds to step S94 to calculate the square sum signal MU, and then proceeds to step S96 to calculate a normalized signal NMU by dividing the square sum signal MU by the square of the digital signal SC. Although the square sum signal. MU depends on the value of the excitation signal Sc, the normalized signal NMU has a value independent of the value of the excitation signal Sc. Step S92 is for preventing the value of the normalized signal NMU from becoming excessively large.

In subsequent step S98, it is determined whether or not the normalized signal NMU is larger or equal to the threshold MUth. If the determination result in step S98 is affirmative, a determination that there is a fault is made in step S100. If the determination result in step S98 is negative, a determination that there is no fault is made in step S102.

When step S100 or S102 is completed, or an affirmative determination is made in step S92, this process is terminated.

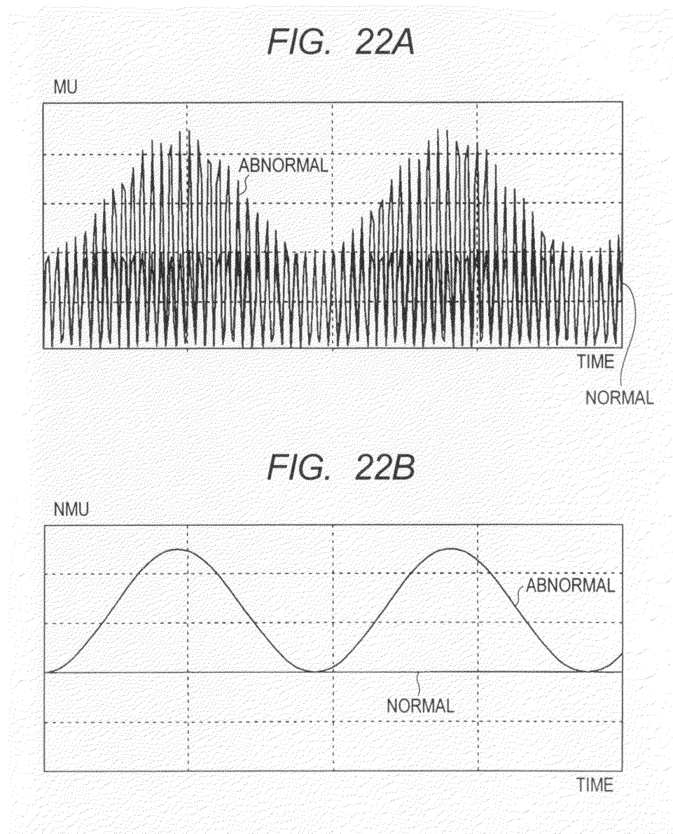

FIG. 22A shows variations with time of the square sum signal MU in each of the normal state and abnormal state. FIG. 228 shows variations with time of the normalized signal NMU in each of the normal state and abnormal state.

As shown in these figures, by normalizing the square sum signal MU, the difference between the normal state and the abnormal state can be emphasized.

According to the twelfth embodiment, other than the above advantages provided by the eleventh embodiment, the following advantage can be provided.

(13) The square sum signal MU is made independent of the effects of variation of the amplitude of the excitation signal Sc. This makes it possible to emphasize the difference between the normal state and the abnormal state.

### Thirteenth Embodiment

Next, a thirteenth embodiment of the invention is described with particular emphasis on the difference with the first embodiment.

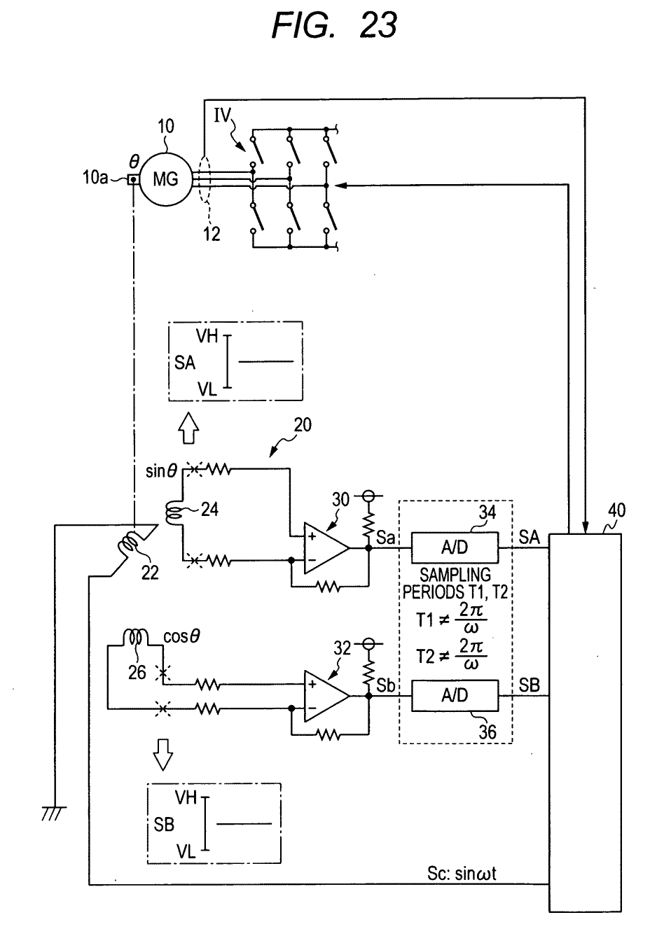

FIG. 23 is a diagram showing the structure of a resolver 20 for use in an M/G 10 as a vehicle main engine, provided with a fault diagnosis device according to a thirteenth embodiment of the invention. In FIG. 23, the reference numerals or characters identical to those in FIG. 1 represent the same elements.

As shown in FIG. 23, in this embodiment, the output terminal of the differential amplifier 30 is pulled up through a resistor, so that the A-phase modulated wave signal Sa is kept at a constant value when there occurs a wire breakage at a position shown by the mark of X. The constant value is set to the center value of the amplitude of the A-phase modulated wave signal Sa, so that the value of the sampled signal outputted from the A/D converter 34 is equal to the middle value between the higher limit value VH and the lower limit value VL. Likewise, the output terminal of the differential amplifier 32 is pulled up through a resistor, so that the s-phase modulated wave signal Sa is kept at a constant value when there occurs a wire breakage at a position shown by the mark of x. The constant value is set to a center value of the amplitude of the B-phase modulated wave signal Sb, so that the value of the sampled signal outputted from the A/D converter 36 is equal to the middle value between the higher limit value VH and the lower limit value VL.

Further, in this embodiment, as the period of the sampling of the sampled signal signals SA and SB, in addition to a first period T1 deferent from the period of 2π/ω of the excitation signal Sc, a second period T2 equal to the period of the excitation signal Sc is used. Preferably, the second period T2 is an integer multiple of the first period T1 less 10 to 50% of the first period, or the first period T1 is an integer multiple of the second period T2 less 10 to 50% of the second period.

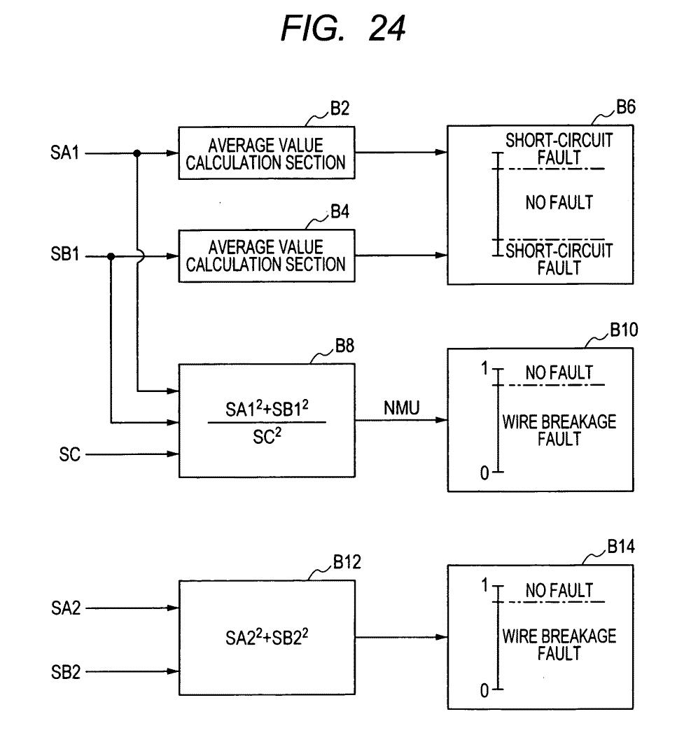

FIG. 24 is a functional block diagram explaining a fault diagnosis process performed by the fault diagnosis device according to the thirteenth embodiment of the invention

An average value calculation section 32 receives the sampled signal SA1 sampled at the first period T1 as time-series data, and calculates an average value of the time-series data. An average value calculation section B4 receives the sampled signal SB1 sampled at the first period T1 as time-series data, and calculates an average value of the time-series data A short-circuit diagnosis section B6 diagnoses presence of a short-circuit fault in the current paths between the secondary coils 24 and 26 and the A/D converters 34 and 36 based on the average values calculated by the average value calculation sections 32 and 34. If there is a ground short in the electrical paths, the sampled signal SA1 or SB1 is fixed to the lower limit value VL, and fixed to the higher limit value VH if there is a short circuit between the electrical paths and the battery. Accordingly, if the difference between the calculated average and the higher limit value or the lower limit value is smaller than a predetermined value, it is determined that there is a short-circuit fault.

Incidentally, even if the rotor is stationary at a position at which the value of sin θ or cos θ is 1 or −1, the average value is near the center value between the higher limit value VH and the lower limit value VL, because the sampled values SA1 and SB1 take various values between the higher limit value VH and the lower limit value VL. In this embodiment, since the sampled signal SA and SB are fixed to the center value when there is a wire breakage, there is no concern that a wire breakage is misdiagnosed as a short-circuit.

A normalized signal calculation section B8 calculates the normalized signal NMU from the sampled signals SA1 and SB1 sampled at the first period T1 inputted thereto as in the case of the twelfth embodiment. A wire breakage diagnosis section B10 diagnoses presence of a wire breakage based on the normalized signal NMU. In this embodiment, a determination that there is a wire breakage is made if the distance between the normalized signal NM and 1 is larger than or equal to a predetermined value. The normalized signal NMU is at 1 in the normal state. When there is a wire breakage, the normalized signal NMU is equal to (sin θ)̂2 or (cos θ)̂2, which may be larger than 1 depending on the rotational angle θ.

A square sum signal calculation section B12 calculates the square sum signal MU from the sampled signals SA2 and SB2 inputted thereto. A wire breakage diagnosis section B14 diagnoses presence of a wire breakage based on the square sum signal MU inputted thereto. In this embodiment, a determination that there is a wire breakage is made if the distance between the square sum signal MT and 1 is larger than or equal to a predetermined value when the sampling timing is in synchronous with the timing at which the excitation signal Sc takes its maximum value. In the normal state, the square sum signal MU is equal to (sin ωt)̂2[(sin θ)̂2+(cos θ)̂2)]=(sin ωt)̂2=1. If a wire breakage is present, the square sum signal MU is equal to (sin ωt sin θ)̂2 or (sin ωt cos θ)̂2, which may be smaller than 1 depending on the phase ωt of the excitation signal Sc.

The reason why both the diagnosis of presence of a wire breakage based on the sampled signals SA1 and SB1 sampled at the first period T1, and the diagnosis of presence of a wire breakage based on the sampled signals SA2 and SB2 sampled at the second period T2 is to determine presence of a wire breakage promptly and accurately even when the period of the sampling cycle and the period of the rotational angle θ are synchronized with each other, or even when the period of the sampling cycle is nearly equal to the period of the rotational angle θ.

When the second period T2 is nearly the same as the period of the modulation wave signals sin θ and cos θ, there is a concern that the time-series data of the square sum signal MU at the second interval T2 remains at around the same value for a long time even when there is a wire breakage. If this value is nearly 1, a determination that there is a wire breakage is not made. However, since the first period T1 is not close to the period of the modulation wave signals sin θ and cos θ, the normalized signal NOM takes various values, and accordingly it is possible to diagnose presence of a wire breakage based on the normalized signal NMU. On the other hand, when the first period T1 is close to the period of the modulation wave signals sin θ and cos θ, there is a concern that the time-series data of the normalized signal NMU at the first interval T1 remains at around 1 for a long time even when there is a wire breakage. However, since the first period T1 is not close to the period of the modulation wave signals sin θ and cos θ, the square sum signal MU takes various values, and accordingly it is possible to diagnose presence of a wire breakage based on the normalized signal MU.

Incidentally, when there is a fault in the resolver 20, controllability of the M/G 10 is deteriorated. Also in this case, the state in which the period of the sampling cycle and the period of the modulation wave signals sine and cos θ are nearly the same with each other may continue for a long time. For example, when the vehicle runs on a sloping road, and the M/G 10 operates in the regenerative mode, there may occur a case where the rotational speed of the M/G 10 is kept at a constant speed (>0) even if the torque of the M/G 10 is uncontrollable.

According to the above thirteenth embodiment, the following advantage can be provided.

(14) The diagnosis of presence of a wire breakage based on the sampled signals SA1 and SB1 sampled at the first period T1, and the diagnosis of presence of a wire breakage based on the sampled signals SA2 and 552 sampled at the second period T2 are both performed. This makes it possible to diagnoses presence of a fault promptly and accurately even when the period of the sampling cycle and the period of the modulation wave signals are synchronized with each other.

(15) The output of the differential amplifier 30 or 32 is set to the middle value between the higher limit value V11 and the lower limit value VL when the connection between the secondary coil 24 or 26 and the differential amplifier 30 or 32 is broken, and a determination that there is a short-circuit fault is made when the sampled signal SA1 or SB1 sampled at the first interval T1 remains at the higher limit value or lower limit value. This makes it possible to diagnosis presence of a short-circuit fault distinguished from a wire breakage fault.

### Fourteenth Embodiment

Next, a fourteenth embodiment of the invention is described with particular emphasis on the difference with the thirteenth embodiment.

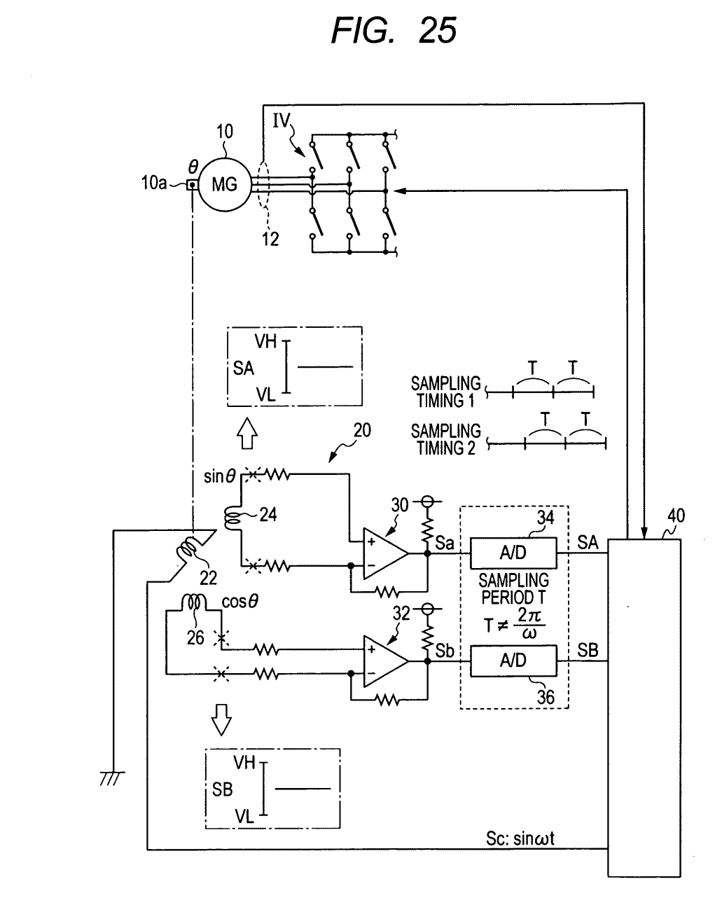

FIG. 25 is a diagram showing the structure of a resolver 20 for use in an M/G 10 as a vehicle main engine, provided with a fault diagnosis device according to a fourteenth embodiment of the invention. In FIG. 25, the reference numerals or characters identical to those in FIG. 23 represent the same elements.

In this embodiment, the sampling is performed at a first sampling timing 1 at the sampling period T, and a second sampling timing 2 at the same sampling timing T different in phase from the first sampling timing 1. The diagnosis of presence of a short-circuit fault or a wire breakage fault is performed based on the sampled signals SA1 and SB1 sampled at the first timing. The diagnosis of presence of a wire breakage fault is performed based on the sampled signals SA2 and 5132 sampled at the second timing. The sampling period T is set different from the period of the excitation signal Sc, and the diagnosis of presence of a wire breakage fault is performed based on the normalized signal for both the case where the sampled signals SA1 and SB1 are used and the case where the sampled signals SA2 and SB2 are used.

Also according to this embodiment, it is possible to deter nine presence of a wire breakage promptly and accurately even when the period of the sampling cycle and the period of the rotational angle θ are synchronized with each other. However, it is preferable that the first sampling timing 1 and the second sampling timing 2 are different in phase from each other by 10 to 50% of their period.

### Fifteenth Embodiment

Next, a fifteenth embodiment of the invention is described with particular emphasis on the differences with the thirteenth embodiment.

In the above thirteenth embodiment, the outputs of the differential amplifiers 30 and 32 are pulled up. According to the thirteenth embodiment, it is possible to hold the output of the differential amplifier 30 or 32 when a wire breakage occurs in the wire between the secondary coil 24 and the differential amplifier 30, or between the secondary coil 26 and the differential amplifier 32. However, the output of the differential amplifier 30 or 32 cannot be fixed when a wire breakage occurs in the secondary coil 24 or 26. This is because two coils resulting from a wire breakage in the secondary coil 24 or 26 are coupled to each other through a parasitic capacitance therebetween. Accordingly, in this case, a voltage smaller than the induced voltage across the secondary coil 24 or 26 in the normal state is induced across the secondary coil 24 or 26.

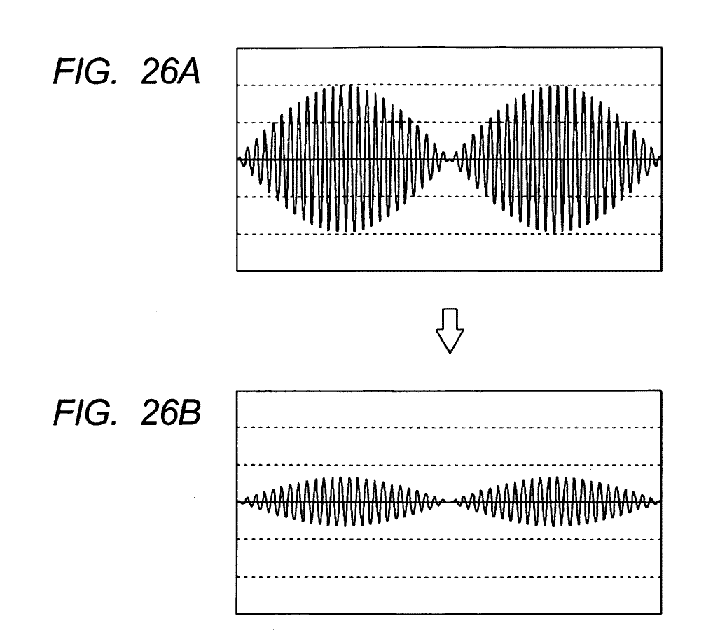

FIG. 26A shows a variation with time of a voltage induced across the secondary coil 24 or 26 in the normal state. FIG. 26B shows a variation with time of a voltage induced across the secondary coil 24 or 26 when a wire breakage is present in the secondary coil 24 or 26. As shown in these figures, when a wire breakage occurs in the secondary coil, the voltage induced across the secondary coil becomes small. This embodiment has a fault diagnosis criterion modified from that of the eighth embodiment to enable detecting such a fault.

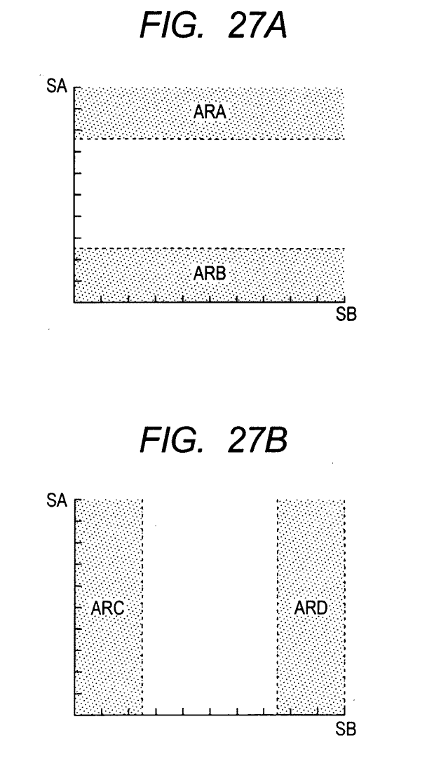

FIGS. 27A and 27B are diagrams explaining the fault diagnosis criterion in this embodiment. In this embodiment, it is determined that there is a wire breakage in the secondary coil 24 or 26, if at least one of the following first and second conditions is satisfied, the first condition being that the sample signal defined by the sampled signals SA and SB does not enter the area ARA or the area ARB shown in FIG. 27A for a time longer than a predetermined time although at least one of the sampled signals SA and SB varies with time, the second condition being that the sample signal does not enter the area ARC or the area ARD for a time longer than the predetermined time shown in FIG. 27B although at least one of the sampled signals SA and SB varies with time. Incidentally, it is not necessary to use the sampled signals SA and SB synchronized with each other to make the above determination. That is, the above determination may be made based on whether or not the sampled signal SA enters the area ARA or ARB, or whether or not the sampled signal SB enter the area ARC or ARD.

### Other Embodiments

It is a matter of course that various modifications can be made to the above embodiments as described below.

As to the sampling means

The object to be sampled is not limited to the modulated wave signals. It may by the carrier wave signal (the excitation signal Sc). Also in this case, it is possible to accurately diagnose a wire breakage in the primary coil of the resolver 20 or the current path of the excitation signal Sc by fixing the detection value of the carrier wave signal to be supplied to the A/D converter if the period of the sampling cycle is set different from the period of the excitation signal Sc.

The sampling means of the first to twelfth embodiments is not limited to the one that performs the sampling at a cycle of the constant period. It may perform the sampling at irregular timings. This can be implemented by use of a random number generator capable of outputting different values associated with different periods of the sampling cycle, one of the different periods being selected depending on the output value of the random number generator.

In the thirteenth embodiment, both the first and second periods T1 and T2 may be different from the period of the carrier wave signal (the excitation signal Sc).

In the fourteenth embodiment, the sampling period T may be the same as the period of the carrier wave signal (the excitation signal Sc). However, in this case, it is preferable that presence of a wire breakage is determined from the results of the diagnosis based on the square sum signal MU of the sampled signals SA1 and SB1, and the diagnosis based on the sampled signals SA2 and SB2. Further, it is preferable that the diagnosis of presence of a short-circuit fault is performed on condition that the M/G 10 is not stationary.

As to the fixing means:

The fixing means of the first to twelfth embodiments is not limited to the one that fixes the input signals of the A/D converters 34 and 36. For example, the A-phase and B-phase modulated wave signals may be fixed to a constant voltage signal. The constant value does not necessarily have to be set above the higher limit value or below the lower limit value of the conversion input range of the A/D converting means. It may be set between the higher limit value and the center value of the conversion input range of the A/D converting means. In this case, it is preferable that the constant value is set to other than the center value (the amplitude center of the modulated wave signal). It is more preferable that the constant value is set distant from the center value by more than half the difference between the higher limit value and the center value. Though it is true that, since both the modulated wave signals are fixed at the center value when their phases are different form each other, it is possible to determine that there is a fault only when both of them are fixed to the center value.

In the thirteenth and fourteenth embodiments, the constant value does not necessary have to be set to the center value between the higher and lower limit values VH and VL. For example, it may be set to the middle value between the higher and lower limit values VH and VL, or to the middle values between this middle value and the lower limit value VL. Also in this case, it is possible to determine presence of a wire breakage promptly and accurately by performing both the fault diagnosis based on the sampled signals SA1 and SB1 and the fault diagnosis based on the sampled signals SA2 and SB2.

The fixing means to pull up or pull down the inputs or outputs of the differential amplifiers does not necessarily have to be provided. For example, if the capacity of the current paths between the secondary coils 24 and 26 and the A/D converters 34 and 36 are large enough to have high noise resistance, it is possible to fix the sampled signals SA and SB, that is, to restrict the variations of the A-phase and B-phase modulated wave signals below the resolution of the A/D converters 34 and 36, when a wire breakage occurs without pulling up or pulling down the inputs or outputs of the differential amplifiers. Also in this case, the fault diagnosis processes described in the seventh embodiment and twelfth embodiment can be performed.

Making a difference between the period of the sampling cycle and the period of the excitation signal Sc is significant for a case in which the input or output terminal of the differential amplifier 30 or 32 is short-circuited to another element, as well as providing the fixing means. By making a difference between the period of the sampling cycle and the period of the excitation signal Sc, it is possible to diagnose presence of a fault based on whether the variations of the sampled signal SA and SB are large or small. When the sampling cycle is synchronized with the excitation signal Sc, if the sampled signal SA or SB is fixed due to a fault there is a concern that the square sum signal MU is fixed at a value close to its normal value, disabling to detect a fault. By making a difference between the period of the sampling cycle and the period of the excitation signal Sc, it is possible to determine that there is a fault when the square sum signal MU takes a value which it cannot take in the normal state.

Further, making a difference between the period of the sampling cycle and the period of the excitation signal Sc irrespective of whether the fixing means is provided or not provides the following technical significance. To completely synchronize the period of the sampling cycle with the period of the excitation signal Sc, a synchronizing circuit is needed, which causes increase of the circuit scale. On the other hand, if such a synchronizing circuit is not provided, when there is a slight difference between the sampling period and the period of the excitation signal Sc, a state where the timing of the sampling significantly deviates from an intended timing may continue for a long time. In this case, it becomes quite difficult to correctly diagnose presence of a fault. By making a difference between the sampling period and the period of the excitation signal Sc, such a problem can be eliminated.

As to the method of diagnosing a fault due to a wire breakage in the secondary coil 24 or 26:

The method of diagnosing a fault due to a wire breakage in the secondary coil 24 or 26 is not limited to the one described in the fifteenth embodiment. For example, since the phenomenon shown in FIG. 26B occurs due to a gain fault, such a fault may be diagnosed using the method described in the eleventh embodiment. Further, such a fault as shown in FIG. 26B may be diagnosed using the method described in the thirteenth or fourteenth embodiment. This is because, when there is a wire breakage in the secondary coil 24 or 26, the square sum signal MU is equal to (sin ωt sin θ)̂2+α(sin ωt cos θ)̂2, or α(sin ωt sin θ)̂2+(sin ωt cos θ)̂2 (α being a numeral value larger than 0 and smaller than 1). For example, (sin ωt sin θ)̂2α(sin ωt cos θ)̂2, which is equal to (sin ωt)̂2+(α−1) (sin ωt cos θ)̂2, is smaller than (sin ωt)̂2.

Further, such a fault as shown in FIG. 26B may be diagnosed using the method described in the sixth embodiment. This is because when the modulation wave signal is α sin θ (0<α<1), the normalized signal NSA is a times that in the normal state, and accordingly the amount of variation itself becomes smaller. Further, such a fault as in FIG. 26B may be diagnosed using the method described in the seventh embodiment.

Incidentally, not only a fault in which the voltage induced in the secondary coil 24 or 26 becomes excessively small, but also a fault in which the voltage induced in the secondary coil 24 or 26 becomes excessively large can be diagnosed by the methods described above. For example, the thirteenth and fourteenth embodiments may be configured to determine that there is a fault if the normalized signal NMU exceeds 1 by a predetermined amount.

As to the deviation monitoring means:

The deviation monitoring means is not limited to the one used in the third, fourth and fifth embodiments. For example, instead of the deviation monitoring means, there may be used a means to determine that there is a fault if a variation range of a certain number of sampled values is smaller than a predetermined value when deviation between the sampled signal and the constant value is small.

As to the variation amount monitoring means:

The variation amount monitoring means is not limited to the one used in the first, second and sixth embodiment. For example, instead of the variation amount monitoring means, there may be used a means to determine that there is a faults if the sampled signal enhanced by the emphasis filter is smaller than a predetermined value.

As to the smoothing filter:

The smoothing filter is not limited to a first-order lag filter. It may be a Butterworth low-pass filter.

As to the phase difference monitoring means:

The phase difference monitoring means is not limited to the one used in the seventh embodiment. For example, instead of the phase difference monitoring means, there may be used a means configured to increment the temporary fault counter C each time it is determined that the absolute value of the sampled signal SB is smaller than or equal to the first threshold, and the absolute value of the sampled signal SA is not larger than or equal to the second threshold, and to determine that there is a fault if the count value of the temporary fault counter C exceeds a threshold before the absolute value of the sampled signal SA becomes larger than or equal to the second threshold. The above configuration works out even if the sampled signals SA and SA are exchanged with each other, when the constant values which the fixing means set for the sampled signals SA and SB are the same.

As to the sum value monitoring means:

The sum value monitoring means does not necessary have to be provided in the ninth, tenth, eleventh or twelfth embodiments. For example, in the eleventh embodiment, instead of the sum value monitoring means, there may used a means to determine that there is a fault if the output of the emphasis filter exceeds a threshold.

As to the prevention means.

The prevention means is not limited to the one used in the thirteenth or fourteenth embodiment. For example, the prevention means may be configured to forcibly change the sampling interval if the variation range of the sampled values is small even when the angular velocity of the modulation wave signal is not zero in the case where the fault diagnosis is performed based on the sole sampling period (2π/ω). It is possible to determine that the angular velocity of the modulation wave signal is not zero by detecting that the M/G 10 shown in FIG. 1 is controlled at a speed not zero, for example.

The diagnosis means to be manipulated by the prevention means is not limited to the one that uses the square sum signal MU. For example, using the prevention means for the diagnosis means in the sixth embodiment is advantageous, because if the normalized signal NSA is used only when the modulation wave signal is small, the accuracy of the diagnosis may be lowered.

As to the resolver:

The resolver is not limited to the one described in the above embodiments that includes the first coil excited by the carrier wave signal to generate magnetic flux, the second coil magnetically coupled with the magnetic flux, and the displacing means to displace at least one of the first and second coils such that part of the magnetic flux interlinking with the second coil periodically varies in intensity. For example, the resolver may have such a structure that a rotor is disposed in a path of a magnetic flux generated by a first coil and interlinking with a second coil, the magnetic flux interlinking with the second coil varying in intensity in accordance with displacement of the rotor.

As to the amplitude modulation device:

The amplitude modulation device is not limited to the resolver in which the phase difference between the A-phase modulated wave signal and the B-phase modulated wave signal is π/2 radians. For example, the fault diagnosis device of the present invention is applicable to a resolver in which the phase difference between the A-phase modulated wave signal and the B-phase modulated wave signal is other than π/2 radians, for example, 30 degrees. However, it is preferable that the phase difference therebetween is other than zero. Though, even when the phase difference is zero, the fault diagnosis in the first to sixth, and eighth embodiments can be implemented.

Although the resolver described above is an amplitude modulation device outputting two wave modulated signals, the present invention is applicable to an amplitude modulation device outputting a single modulated wave signal such as an AM modulator for use in an AM radio transmitter. Further, the present invention is applicable to an amplitude modulation device outputting three or more modulated wave signals. The means to inhibit the fault diagnosis process when the value of the carrier wave is close to zero may be used in the embodiments which do not use the normalized signal. For example, such means may be provided in the first embodiment, because when the value of the carrier wave signal is close to zero, a variation range of the sampled values is small even in the normal state.

In the eleventh embodiment, although presence of a fault in which the A-phase modulated wave signal or B-phase modulated wave signal becomes large is diagnosed, presence of a fault in which the A-phase modulated wave signal or B-phase modulated wave signal becomes small may also be diagnosed. This can be implemented by detecting whether the sampled signal having been subjected to the filtering process is smaller than a threshold.

The thirteenth and fourteenth embodiments may be modified such that presence of a short-circuit fault or a wire breakage fault is diagnosed based on the square sum signal NMU or normalized signal NMU.

The above explained preferred embodiments are exemplary of the invention of the present application which is described solely by the claims appended below. It should be understood that modifications of the preferred embodiments may be made as would occur to one of skill in the art.

What is claimed is:

1. A fault diagnosis device for diagnosing presence of a fault in an amplitude modulation device which modulates an amplitude of a carrier wave signal to generate a modulated wave signal, comprising
a sampling means to perform sampling of at least one of the carrier wave signal and the modulated wave signal at a period different from a period of the carrier wave signal and
a diagnosis means to perform diagnosis of presence of a fault in the amplitude modulation device based on sampled values outputted from the sampling means.

2. The fault diagnosis device according to claim 1, wherein the sampling means samples the modulated wave signal.

3. The fault diagnosis device according to claim 2, wherein the amplitude modulation device includes an output means to output the modulated wave signal, and a modulated wave signal fixing means to fix the modulated wave signal outputted from the output means at a constant signal value, when there is a wire breakage in a signal path between the output means and the sampling means.

4. The fault diagnosis device according to claim 3, wherein the constant signal value is different from a value of an amplitude center of the modulated wave signal.

5. The fault diagnosis device according to claim 2, wherein the amplitude modulation device includes a first coil excited by the carrier wave signal to generate magnetic flux and a second coil magnetically coupled with the magnetic flux, and is configured such that part of the magnetic flux interlinking with the second coil periodically varies in intensity so that a voltage is induced in the second coil as the modulated wave signa.

6. The fault diagnosis device according to claim 5, wherein the sampling means includes a voltage converter means to convert an output signal of the second coil into a voltage signal within a predetermined voltage range, an A/D converter means to convert the voltage signal into digital data, and a digital processing means to diagnosis presence of a fault in the amplitude modulation device based on the digital data, the voltage converter means including an output fixing means to fix an output thereof at a constant voltage value when a connection between the voltage converter means and the second coil is broken.

7. The fault diagnosis device according to claim 6, wherein the constant voltage value is different from a voltage value of an amplitude center value of the modulated wave signal.

8. The fault diagnosis device according to claim 3, wherein the diagnosis means includes a deviation monitoring means to diagnose presence of a fault based on deviation between sampled values outputted from the sampling means and the constant signal value.

9. The fault diagnosis device according to claim 6, wherein the diagnosis means includes a deviation monitoring means to diagnose presence of a fault based on deviation between sampled values outputted from the sampling means and the constant voltage value.

10. The fault diagnosis device according to claim 2, wherein the diagnosis means includes a variation amount monitoring means to determine that there is a fault when a variation amount of sampled values outputted from the sampling means is smaller than a predetermined value.

11. The fault diagnosis device according to claim 8, wherein the diagnosis means performs the diagnosis based on sampled values outputted from the sampling means having been subjected to a filtering process.

12. The fault diagnosis device according to claim 10, wherein the diagnosis means performs the diagnosis based on sampled values outputted from the sampling means having been subjected to a filtering process.

13. The fault diagnosis device according to claim 11, wherein the filtering process is a smoothing process performed by a smoothing filter.

14. The fault diagnosis device according to claim 12, wherein the filtering process is a smoothing process performed by a smoothing filter.

15. The fault diagnosis device according to claim 10, wherein the diagnosis means quantifies the variation amount as a variation rate of the sampled values.

16. The fault diagnosis device according to claim 10, wherein the diagnosis means quantifies the variation amount based on at least one of a maximum value, a minimum value, a standard deviation, a variance and a kurtosis of the sampled values sampled within a predetermined time period.

17. The fault diagnosis device according to claim 10, wherein
the amplitude modulation device is a resolver for detecting a rotational angle of a rotating machine,
the fault diagnosis device further comprising a rotational angle estimation means to estimate the rotational angle of the rotating machine based on an electrical state of the rotating machine, and
the variation amount monitoring means performs the diagnosis based on the variation amount when the modulated wave signal has been subjected to an amplitude demodulation process in accordance with the rotational angle estimated by the rotational angle estimation means.

18. The fault diagnosis device according to claim 1, wherein the modulated wave signal is constituted of first and second modulated wave signals generated by modulating the carrier wave signal with two modulation wave signals having different phases from each other, the sampling means samples the first and second modulated wave signals, and the diagnosis means determines that there is a fault if differences in value between the sampled values of the first modulated wave signal and the sampled values of the second modulated wave signal do not reach a predetermined value.

19. The fault diagnosis device according to claim 2, wherein the modulated wave signal is constituted of first and second modulated wave signals generated by modulating the carrier wave signal with two modulation wave signals having different phases from each other, the sampling means samples the first and second modulated wave signals, and the diagnosis means diagnoses presence of a fault based on a distribution of the sampled values in a two-dimensional coordinate system whose coordinate axes represent the sampled values of the first and second modulated wave signals, respectively.

20. The fault diagnosis device according to claim 2, wherein the modulated wave signal is constituted of first and second modulated wave signals generated by modulating the carrier wave signal with two modulation wave signals having different phases from each other, and the diagnosis means includes a sum value monitoring means to diagnose presence of a fault based on comparison between a threshold and a sum value of each sampled value of the first modulated wave signal and each corresponding sampled value of the second modulated wave signal.

21. The fault diagnosis device according to claim 2, wherein the modulated wave signal is constituted of first and second modulated wave signals generated by modulating the carrier wave signal with two modulation wave signals having different phases from each other by π/2 radians, and the diagnosis means includes a sum value monitoring means to diagnose presence of a fault based on a sum value of a square of each sampled value of the first modulated wave signal and a square of each corresponding sampled value of the second modulated wave signal.

22. The fault diagnosis device according to claim 20, wherein the sampling means performs the sampling at a sampling period different from a period of the carrier wave signal, the sum value monitoring means diagnoses presence of a fault based on the sum value having been subjected to a filtering process by an emphasis filter, and the emphasis filter outputs the sum value multiplied by a multiplier varying at a period equal to a common multiple of the period of the carrier wave signal and the sampling period.

23. The fault diagnosis device according to claim 21, wherein the sampling means performs the sampling at a sampling period different from a period of the carrier wave signal, the sum value monitoring means diagnoses presence of a fault based on the sum value having been subjected to a filtering process by an emphasis filter, and the emphasis filter outputs the sum value multiplied by a multiplier varying at a period equal to a common multiple of the period of the carrier wave signal and the sampling period.

24. The fault diagnosis device according to claim 22, wherein all values of the varying multiplier are of the same sign.

25. The fault diagnosis device according to claim 22, wherein the sum value monitoring means diagnoses presence of a fault based on an output of the emphasis filter having been subjected to a smoothing process by a smoothing filter.

26. The fault diagnosis device according to claim 24, wherein the sum value monitoring means diagnoses presence of a fault based on an output of the emphasis filter having been subjected to a smoothing process by a smoothing filter.

27. The fault diagnosis device according to claim 20 wherein the sum value monitoring means includes an elimination means to eliminate effect of amplitude variation of the carrier wave signal from the sum value inputted thereto, and diagnoses presence of a fault based on an output of the elimination means.

28. The fault diagnosis device according to claim 1 wherein the sampling means performs the sampling at a predetermined period.

29. The fault diagnosis device according to claim 3, wherein
the modulated wave signal is constituted of first and second modulated wave signals generated by modulating the carrier wave signal with two modulation wave signals having different phases from each other by π/2 radians,
the sampling means performs the sampling at each of first and second cycles having different phases from each other, and
the diagnosis means includes a sum value monitoring means to diagnose presence of a fault based on both a sum value of a pair of each sampled value of the first modulated wave signal and each corresponding sampled value of the second modulated wave signal sampled at the first cycle, and a sum value of a pair of each sampled value of the first modulated wave signal and each corresponding sampled value of the second modulated wave signal sampled at the second cycle.

30. The fault diagnosis device according to claim 3, wherein
the modulated wave signal is constituted of first and second modulated wave signals generated by modulating the carrier wave signal with two modulation wave signals having different phases from each other by π/2 radians,
the sampling means performs the sampling at each of first and second cycles having the same period and having different phases from each other, and
the diagnosis nears includes a sum value monitoring means to diagnose presence of a fault based on both a sum value of a pair of each sampled value of the first modulated wave signal and each corresponding sampled value of the second modulated wave signal sampled at the first cycle, and a sum value of a pair of each sampled value of the first modulated wave signal and each corresponding sampled value of the second modulated wave signal sampled at the second cycle.

31. The fault diagnosis device according to claim 29, wherein,
the constant signal value is set between a higher limit value and a lower limit value of the modulated wave signal,
a period of the first cycle is different from the period of the carrier wave signal, and
the diagnosis means determines that there is a short-circuit fault in the amplitude modulation device if differences between the sampled values sampled at the first cycle and the higher or lower limit value are smaller than or equal to a predetermined value.

32. The fault diagnosis device according to claim 30, wherein,
the constant signal value is set between a higher limit value and a lower limit value of the modulated wave signal,
a period of the first cycle is different from the period of the carrier wave signal, and
the diagnosis means determines that there is a short-circuit fault in the amplitude modulation device if differences between the sampled values sampled at the first cycle and the higher or lower limit value are smaller than or equal to a predetermined value.

33. A fault diagnosis device for diagnosing presence of a fault in an amplitude modulation device which modulates an amplitude of a carrier wave signal to generate a modulated wave signal, comprising:
a sampling means to perform sampling of the modulated wave signal; and
a diagnosis means to perform diagnosis of presence of a fault based on sampled values of the modulated wave signal outputted from the sampling means,
wherein the sampling means includes a prevention means to prevent the diagnosis from being performed by the diagnosis means based on only the sampled values sampled at the same phase.

34. The fault diagnosis device according to claim 33, wherein the sampling means performs the sampling at each of first and second cycles having different phases from each other, and the prevention means causes the diagnosis means to perform the diagnosis based on the sampled values sampled at the first cycle, and the diagnosis based on the sampled values sampled at the second cycle.

35. The fault diagnosis device according to claim 33, wherein the sampling means performs the sampling at each of first and second cycles having the same period and having different phases from each other, and the prevention means causes the diagnosis means to perform the diagnosis based on the sampled values sampled at the first cycle, and the diagnosis based on the sampled values sampled at the second cycle.

36. The fault diagnosis device according to claim 34, wherein
the modulated wave signal is constituted of first and second modulated wave signals generated by modulating the carrier wave signal with two modulation wave signals having different phases from each other by π/2 radians, and
the diagnosis means includes a sum value monitoring means to diagnose presence of a fault based on both a sum value of a pair of each sampled value of the first modulated wave signal and each corresponding sampled value of the second modulated wave signal sampled at the first cycle, and a sum value of a pair of each sampled value of the first modulated wave signal and each corresponding sampled value of the second modulated wave signal sampled at the second cycle.

37. The fault diagnosis device according to claim 35, wherein
the modulated wave signal is constituted of first and second modulated wave signals generated by modulating the carrier wave signal with two modulation wave signals having different phases from each other by π/2 radians, and
the diagnosis means includes a sum value monitoring means to diagnose presence of a fault based on both a sum value of a pair of each sampled value of the first modulated wave signal and each corresponding sampled value of the second modulated wave signal sampled at the first cycle, and a sum value of a pair of each sampled value of the first modulated wave signal and each corresponding sampled value of the second modulated wave signal sampled at the second cycle.
